(19) United States
(12) Patent Application Publication
(10) Pub. No.: US 2014/0145707 A1
(43) Pub. Date: May 29, 2014

(54) VOLTAGE FLUCTUATION DETECTION CIRCUIT AND SEMICONDUCTOR INTEGRATED CIRCUIT

(71) Applicant: FUJITSU LIMITED, Kawasaki-shi (JP)

(72) Inventors: Satoshi Tanabe, Kawasaki (JP); Kenichi Kawasaki, Kawasaki (JP)

(73) Assignee: FUJITSU LIMITED, Kawasaki-shi (JP)

(21) Appl. No.: 14/038,315

(22) Filed: Sep. 26, 2013

(30) Foreign Application Priority Data
Nov. 27, 2012 (JP) 2012-259127

(51) Int. Cl. G01R 23/15

(52) U.S. Cl. CPC G01R 23/15
USPC 324/76.41

(57) ABSTRACT

A voltage fluctuation detection circuit includes an oscillation circuit configured to receive an operation voltage and perform an oscillation operation, an operation voltage generation unit configured to reduce a detection target voltage and generate the operation voltage, and a fluctuation detection unit configured to measure an oscillation frequency of the oscillation circuit and detect a fluctuation of the detection target voltage.

### CROSS-REFERENCE TO RELATED APPLICATION

This application is based upon and claims the benefit of priority of the prior Japanese Patent Application No. 2012-259127, filed on Nov. 27, 2012, the entire contents of which are incorporated herein by reference.

### FIELD

The embodiments discussed herein are related to a voltage fluctuation detection circuit and a semiconductor integrated circuit.

### BACKGROUND

Up to now, a technique using an oscillation circuit (for example, a ring oscillator) has been proposed to detect fluctuations of a power supply voltage that are caused as a result of noise generated in a semiconductor integrated circuit. The fluctuation of the power supply voltage is detected by measuring an oscillation frequency of the oscillation circuit, which is driven at the power supply voltage according to this technique.

See Japanese Laid-open Patent Publication No. 8-18339, Japanese Laid-open Patent Publication No. 2010-103971, and Japanese Laid-open Patent Publication No. 8-68814.

According to the technique using the oscillation circuit as described above, a problem occurs such that any fluctuation of the oscillation frequency is small with respect to the fluctuation of the power supply voltage. As such, if the oscillation circuit is to be used as a voltage sensor, its fluctuation detection sensitivity is low.

### SUMMARY

According to the present aspects, a voltage fluctuation detection circuit is described. The voltage fluctuation detection circuit may include an oscillation circuit configured to receive an operation voltage and perform an oscillation operation. The voltage fluctuation detection circuit may include an operation voltage generation unit configured to reduce a detection target voltage and generate the operation voltage. The voltage fluctuation detection circuit may include a fluctuation detection unit configured to measure an oscillation frequency of the oscillation circuit and detect a fluctuation of the detection target voltage.

According to the present aspects, a semiconductor integrated circuit that includes a voltage fluctuation detection circuit is described. The voltage fluctuation detection circuit included in the semiconductor integrated circuit may include an oscillation circuit configured to receive an operation voltage and perform an oscillation operation. The voltage fluctuation detection circuit included in the semiconductor integrated circuit may include an operation voltage generation unit configured to reduce a detection target voltage and generate the operation voltage. The voltage fluctuation detection circuit included in the semiconductor integrated circuit may include a fluctuation detection unit configured to measure an oscillation frequency of the oscillation circuit and detect a fluctuation of the detection target voltage.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates examples of a semiconductor integrated circuit and a voltage fluctuation detection circuit according to a first embodiment;

FIG. 2 illustrates examples of a semiconductor integrated circuit and a voltage fluctuation detection circuit according to a second embodiment;

FIG. 3 is a timing chart that illustrates an example of a first operation of the voltage fluctuation detection circuit according to the second embodiment;

FIG. 4 is a partially enlarged view of the timing chart of FIG. 3 according to the present aspects;

FIG. 5 is a timing chart for illustrating an example of a second operation of the voltage fluctuation detection circuit according to the second embodiment;

FIG. 6 illustrates results of an example simulation for a power supply voltage dependency of the operation voltage of the oscillation circuit that results from a difference in power supply rejection ratio (PSRR) of an operation voltage generation unit according to the present aspects;

FIG. 7A and FIG. 7B illustrate results of example simulations regarding the power supply voltage dependency of the oscillation frequency of the oscillation circuit and the oscillation frequency fluctuation rate depending on the presence or absence of the operation voltage generation unit according to the present aspects;

FIG. 8 illustrates examples of a semiconductor integrated circuit and a voltage fluctuation detection circuit according to a third embodiment;

FIG. 9 is a timing chart for illustrating an example of an operation of the voltage fluctuation detection circuit according to the third embodiment;

FIG. 10 illustrates results of an example simulation for a voltage dependency of the operation voltage of the oscillation circuit due to a difference in PSRR of the operation voltage generation unit according to the present aspects;

FIG. 11A and FIG. 11B illustrate results of an example simulation regarding the voltage dependency of the oscillation frequency of the oscillation circuit and the oscillation frequency fluctuation rate depending on the presence or absence of the operation voltage generation unit according to the present aspects;

FIG. 12 illustrates examples of a semiconductor integrated circuit and a voltage fluctuation detection circuit according to a fourth embodiment;

FIG. 13 illustrates a result of an example simulation for a voltage dependency of the operation voltage of the oscillation circuit in the voltage fluctuation detection circuit according to the fourth embodiment;

FIG. 14A and FIG. 14B illustrate results of an example simulation regarding the voltage dependency of the oscillation frequency of the oscillation circuit and the oscillation frequency fluctuation rate depending on the presence or absence of the operation voltage generation unit according to the present aspects;

FIG. 15 illustrates examples of a semiconductor integrated circuit and a voltage fluctuation detection circuit according to a fifth embodiment;

FIG. 16 illustrates an example of a circuit representing the operation voltage generation unit and the oscillation circuit by a resistance component and a capacitance component according to the present aspects;

FIG. 17 illustrates an example of a state of a transient response of the voltage and the operation voltage of the oscillation circuit according to the present aspects;

FIG. 18 illustrates examples of a semiconductor integrated circuit and a voltage fluctuation detection circuit according to a sixth embodiment;

FIG. 19 illustrates a cross sectional view of an example P-type metal-oxide-semiconductor (pMOS) included in the oscillation circuit according to the present aspects;

FIG. 20 illustrates results of an example simulation for the voltage dependency of the operation voltage of the oscillation circuit in the voltage fluctuation detection circuit according to the sixth embodiment;

FIG. 21A and FIG. 21B illustrate results of example simulations regarding the voltage dependency of the oscillation frequency of the oscillation circuit and the oscillation frequency fluctuation rate according to the present aspects;

FIG. 22 illustrates examples of a semiconductor integrated circuit and a voltage fluctuation detection circuit according to a seventh embodiment;

FIG. 23 is a timing chart that illustrates an example operation of the voltage fluctuation detection circuit according to the seventh embodiment;

FIG. 24 illustrates examples of a semiconductor integrated circuit and a voltage fluctuation detection circuit according to an eighth embodiment;

FIG. 25 illustrates examples of a semiconductor integrated circuit and a voltage fluctuation detection circuit according to a ninth embodiment;

FIG. 26 illustrates a cross sectional view of an example N-type metal-oxide-semiconductor (nMOS) included in the oscillation circuit according to the present aspects;

FIG. 27 illustrates examples of a semiconductor integrated circuit and a voltage fluctuation detection circuit according to a tenth embodiment; and

FIG. 28 is a timing chart that illustrates an example operation of the voltage fluctuation detection circuit according to the tenth embodiment.

### DESCRIPTION OF EMBODIMENTS

Hereinafter, embodiments for carrying out the present aspects will be described with reference to the drawings.

### First Embodiment

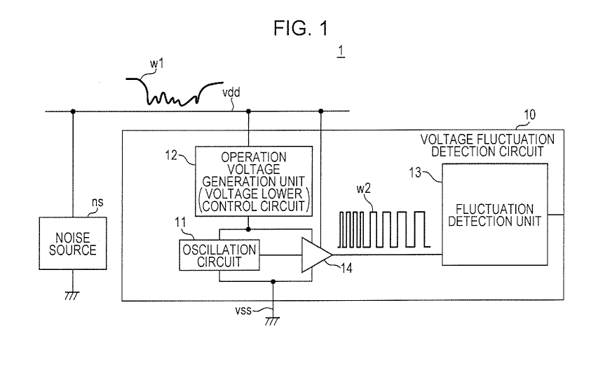

FIG. 1 illustrates examples of a semiconductor integrated circuit and a voltage fluctuation detection circuit according to a first embodiment.

A semiconductor integrated circuit 1 includes a wiring (e.g., power supply wiring) vdd, a wiring (e.g., grounding wire) vss, and a voltage fluctuation detection circuit 10. In the example of the semiconductor integrated circuit 1, and according to the first embodiment, the wiring vdd is set as a power supply potential, and the wiring vss is set as a reference potential (e.g., grounding potential). A waveform 1 represents a change of the power supply potential caused by a noise source ns that is connected to the wiring vdd.

The voltage fluctuation detection circuit 10, according to the first embodiment, is configured to detect a fluctuation of a voltage (e.g., power supply voltage) between the wiring vdd and the wiring vss and includes an oscillation circuit 11, an operation voltage generation unit 12, a fluctuation detection unit 13, and a level shifter 14.

The oscillation circuit 11 receives an operation voltage generated by the operation voltage generation unit 12 and performs an oscillation operation. An output signal (e.g., oscillation signal) of the oscillation circuit 11 is input to the fluctuation detection unit 13 via the level shifter 14. The oscillation circuit 11 is also connected to the wiring vss. The oscillation circuit 11 is, for example, a ring oscillator or the like.

The operation voltage generation unit 12 is configured to reduce a detection target voltage and generate operation voltages of the oscillation circuit 11 and the level shifter 14. The detection target voltage is a power supply voltage according to the example of the voltage fluctuation detection circuit 10. The operation voltage generation unit 12 is connected to the wiring vdd and generates a voltage that is lower than the potential of the wiring vdd. The operation voltage generation unit 12 supplies the generated voltage to the oscillation circuit 11 as the operation voltage of the oscillation circuit 11. The operation voltage generation unit 12 thus functions as a voltage lower control circuit configured to reduce the power supply voltage.

The operation voltage generation unit 12 is configured to generate the operation voltage that fluctuates in accordance with the fluctuation of the detection target voltage. To elaborate, the operation voltage generation unit 12 conveys the fluctuation of the power supply voltage onto the operation voltage of the generated oscillation circuit 11. For this reason, the operation voltage generation unit 12 may desirably have a low power supply rejection ratio (PSRR). This is because the fluctuation of the power supply voltage increases the influence of the oscillation circuit 11a on an oscillation frequency and raises a detection accuracy in the fluctuation detection unit 13. In addition, an effect is also attained in which the power consumption can be decreased if the PSRR is low (e.g., see expressions (6), (8), and/or the like which will be described below). In the case of the present example, the PSRR is represented by “a change of the potential of the wiring vdd/a change of the operation voltage”. An example of the operation voltage generation unit 12 having the low PSRR includes a (diode-connected) metal-oxide semiconductor field effect transistor (MOSFET) where its own gate is connected to its own drain.

The fluctuation detection unit 13 is configured to receive the output signal of the oscillation circuit 11 (an example of which is represented by a waveform w2), which is transmitted via the level shifter 14 and measures an oscillation frequency of the oscillation circuit 11a to detect a fluctuation of the voltage. The detection result is output to an external part of the voltage fluctuation detection circuit 10 and is output, for example, from an external terminal (not illustrated) of the semiconductor integrated circuit 1. The fluctuation detection unit 13 is configured to count, for example, the number of rising edges of the waveform w2 in unit time and detect the voltage fluctuation on the basis of the change. For example, when the voltage is reduced because of the noise influence, the number of counts per unit time is decreased.

The level shifter 14 is configured to adjust an amplitude of the output signal of the oscillation circuit 11 in accordance with an amplitude of the operation voltage of the fluctuation detection unit 13. In the example of the voltage fluctuation detection circuit 10, and according to the first embodiment, the fluctuation detection unit 13 is operated at a potential level of the wiring vdd (that is, the power supply voltage). For that reason, the level shifter 14 is connected to the wiring vdd and is configured to change the amplitude of the output signal where the voltage is reduced in the oscillation circuit 11 to the potential level of the wiring vdd. As such, the fluctuation detection unit 13 can accurately detect the oscillation frequency. For example, if the fluctuation detection unit 13 also is operated at the signal level of the output signal of the oscillation circuit 11 and can detect the output signal of the oscillation circuit 11. As such, the level shifter 14 may be omitted.

With aspects of the voltage fluctuation detection circuit 10 configured as described above, the oscillation circuit 11 is operated according to an operation obtained by reducing the voltage of the detection target. As such, it is possible to increase an oscillation frequency fluctuation rate of the oscillation circuit 11a. Since the oscillation frequency fluctuation rate is a sensitivity at which the voltage can be detected in the voltage fluctuation detection circuit 10, the sensitivity can be raised by increasing the oscillation frequency fluctuation rate. In addition, the power consumption of the oscillation circuit 11 is suppressed by increasing the oscillation frequency fluctuation rate, and as a result, the power consumption of the voltage fluctuation detection circuit 10 and the semiconductor integrated circuit 1 are suppressed.

Hereinafter, the above-discussed aspects will be described with respect to the following mathematical expressions.

In the following expressions (1) to (7), the operation voltage of the oscillation circuit 11 is set as a power supply voltage V_{DD}, and a relationship between a magnitude of the power supply voltage V_{DD} and consumed energy Eₜₒₜₐₗ will be described.

If, for example, a ring oscillator is used as the oscillation circuit 11, an oscillation frequency f_{rosc} of the oscillation circuit 11a can be represented, for example, by the following expression (1).

$${f}_{rosc} = \frac{1}{{T}_{rosc}} = \frac{1}{2 ( 2 N + 1 ) τ} \qquad ( 1 )$$

In the expression (1), 2N+1 corresponds to the number of poles of the inverter circuits included in the oscillation circuit 11, and τ denotes the signal propagation delay of the inverter circuit. On the other hand, the signal propagation delay τ of the inverter circuit is represented by the following expression (2).

$$τ \approx \frac{{KC}_{inv} {V}_{DD}}{μ {C}_{OX} ( \frac{W}{L} ) {( {V}_{DD} - {V}_{th} )}^{α}} = \frac{{KC}_{inv} {V}_{DD}}{{β ( {V}_{DD} - {V}_{th} )}^{α}} \qquad ( 2 )$$

In the expression (2), β represents β=μCₒₓ(W/L), where μ denotes an electron mobility, and Cₒₓ, W, and L respectively denote a gate capacitance, a gate width, and a gate length of a transistor used in the oscillation circuit 11 per unit area. K denotes a proportionality coefficient, V_{DD} denotes a power supply voltage, Vₜₕ denotes a threshold voltage of the transistor, and α corresponds to a value that depends on a short channel effect and is empirically assigned, which is approximately 1 to 2. Cᵢₙᵥ denotes an average load capacitance appearing per inverter circuit when the inverter circuits are driven. When the expression (2) is substituted for the expression (1), the following expression (3) is derived.

$$\begin{matrix}{f}_{rosc} = \frac{1}{2 ( 2 N + 1 ) τ} \\ = \frac{β}{2 ( 2 N + 1 ) {KC}_{inv}} \frac{{( {V}_{DD} - {V}_{th} )}^{α}}{{V}_{DD}}\end{matrix} \qquad ( 3 )$$

When the expression (3) is used, the consumed energy Eₜₒₜₐₗ of the voltage fluctuation detection circuit 10 can be represented, for example, by the following expression (4).

$$\begin{matrix}{E}_{total} = {E}_{rosc} + {E}_{counter} \\ \approx ( 2 N + 1 ) {C}_{inv} {V}_{DD}^{2} {f}_{rosc} {T}_{meas} + {α}_{gate} {n}_{gate} {C}_{gate} {V}_{DD}^{2} {f}_{rosc} {T}_{meas} \\ = \frac{β}{2 K} {( {V}_{DD} - {V}_{th} )}^{α} {V}_{DD} {T}_{meas} + {α}_{gate} {n}_{gate} {C}_{gate} {V}_{DD}^{2} {f}_{rosc} {T}_{meas} \\ = ( \frac{β}{2 K} {( {V}_{DD} - {V}_{th} )}^{α} {V}_{DD} + {α}_{gate} {n}_{gate} {C}_{gate} {V}_{DD}^{2} {f}_{rosc} ) {T}_{meas}\end{matrix} \qquad ( 4 )$$

In the expression (4), E_{rosc} and E_{counter}, respectively, denote consumption energy of the oscillation circuit 11 and consumption energy of the fluctuation detection unit 13. α_{gate} denotes an operation factor of the fluctuation detection unit 13, n_{gate} denotes the number of gates of the fluctuation detection unit 13, and C_{gate} denotes an average load capacitance appearing per logic gate circuit when logic gate circuits included in the fluctuation detection unit 13 are driven. Tₘₑₐₛ denotes a measurement time.

As represented by the expression (4), the consumed energy Eₜₒₜₐₗ is in proportion to the measurement time Tₘₑₐₛ.

On the other hand, a relationship illustrated in the following expression (5) is established among the oscillation frequency f_{rosc}, the measurement time Tₘₑₐₛ, and a measurement accuracy S.

$$\begin{matrix}S ≡ \frac{\partial {C}_{ount}}{\partial {V}_{DD}} \\ = \frac{\partial {f}_{rosc}}{\partial {V}_{DD}} \cdot {T}_{meas} \\ = ( \frac{( α - 1 ) {V}_{DD} + {V}_{th}}{{V}_{DD} ( {V}_{DD} - {V}_{th} )} ) \cdot {f}_{rosc} \cdot {T}_{meas} \\ = λ ( {V}_{DD} , {V}_{th} ) \cdot {f}_{rosc} \cdot {T}_{meas}\end{matrix} \qquad ( 5 )$$

The measurement accuracy S is in proportion to the oscillation frequency f_{rosc} and the measurement time Tₘₑₐₛ as represented in the expression (5). In a case where a counter is used in the fluctuation detection unit 13, for example, the measurement accuracy S is defined as a fluctuation rate (e.g., differential value) based on the power supply voltage V_{DD} of a count value Cₒᵤₙₜ of the rising edges of the waveform w2. λ (V_{DD}, Vₜₕ) denotes a sensitivity (e.g., oscillation frequency fluctuation rate). From the expression (4) and the expression (5), the consumed energy Eₜₒₜₐₗ, the measurement accuracy S, and the oscillation frequency fluctuation rate λ establish a relationship represented in the following expression (6).

$${E}_{total} ∝ {T}_{meas} = \frac{S}{{f}_{rosc} \cdot λ ( {V}_{DD} , {V}_{th} )} \qquad ( 6 )$$

As in the expression (6), under a condition where the measurement accuracy S is fixed, the consumed energy Eₜₒₜₐₗ is decreased as the oscillation frequency fluctuation rate λ is increased.

When the expression (5) is transformed by focusing attention on the oscillation frequency fluctuation rate λ, the oscillation frequency fluctuation rate λ (V_{DD}, Vₜₕ) at the time of a certain power supply voltage V_{DD} and a certain threshold voltage Vₜₕ, can be represented as the following expression (7).

$$λ ( {V}_{DD} , {V}_{th} ) ≡ \frac{S}{{f}_{rosc} \cdot {T}_{meas}} = \frac{1}{{f}_{rosc}} \frac{\partial {f}_{rosc}}{\partial {V}_{DD}} = \frac{( α - 1 ) {V}_{DD} + {V}_{th}}{{V}_{DD} ( {V}_{DD} - {V}_{th} )} \qquad ( 7 )$$

From the expression (7), if the power supply voltage V_{DD} is reduced or the threshold voltage Vₜₕ is increased, it is possible to increase the oscillation frequency fluctuation rate λ (V_{DD}, Vₜₕ).

When aspects of the voltage fluctuation detection circuit 10 are configured according to the first embodiment, the operation voltage generation unit 12 is configured to reduce the power supply voltage V_{DD} (e.g., potential difference between the wiring vdd and the wiring vss) to generate the operation voltage of the oscillation circuit 11, so that it is possible to increase the oscillation frequency fluctuation rate λ of the oscillation circuit 11a.

For that reason, as may be understood from the expression (6), even under the condition where the measurement accuracy S is fixed, the consumed energy Eₜₒₜₐₗ of the voltage fluctuation detection circuit 10 can be decreased so that it is possible to reduce the power consumption.

In the voltage fluctuation detection circuit 10, according to the first embodiment, the oscillation frequency fluctuation rate λ can also be represented by the following expression (8).

$$\begin{matrix}λ = \frac{1}{{f}_{rosc}} \frac{\partial {f}_{rosc}}{\partial {V}_{DD}} \\ = \frac{1}{{f}_{rosc}} \frac{\partial {f}_{rosc}}{\partial {V}_{DDV}} \frac{\partial {V}_{DDV}}{\partial {V}_{DD}} \\ = \frac{1}{{f}_{rosc}} \frac{\partial {f}_{rosc}}{\partial {V}_{DDV}} \frac{1}{PSRR}\end{matrix} \qquad ( 8 )$$

In the expression (8), V_{DDV} denotes an operation voltage generated when the power supply voltage V_{DD} is reduced by the operation voltage generation unit 12. The change amount of “the power supply voltage V_{DD}/the change amount of the operation voltage V_{DDV}” corresponds to the above-mentioned PSRR. As may be understood from the expression (8), the oscillation frequency fluctuation rate λ also can be increased by decreasing the PSRR, and the consumed energy Eₜₒₜₐₗ of the voltage fluctuation detection circuit 10 can be reduced, so that it is possible to reduce the power consumption.

As represented by the expression (4), since the power consumption of the oscillation circuit 11 using the ring oscillator is in proportion to the number of poles of the inverter circuits (e.g., the measurement time Tₘₑₐₛ in the above-mentioned expression (6) is determined on the basis of the number of poles of the inverter circuits), and in order for the power consumption to be suppressed, the number of poles of the inverter circuits may be decreased. As represented by the expression (3), since the number of poles of the inverter circuits is in inverse proportion to a delay time of the inverter circuit, and in order for the power consumption to be suppressed, the delay time of the inverter circuit may be increased to decrease the number of poles of the inverter circuits. The delay time of the inverter circuit can be increased by reducing the operation voltage the oscillation circuit or increasing the threshold voltage Vₜₕ. Thus, the power consumption can be suppressed by reducing the operation voltage with the above-mentioned technique.

### Second Embodiment

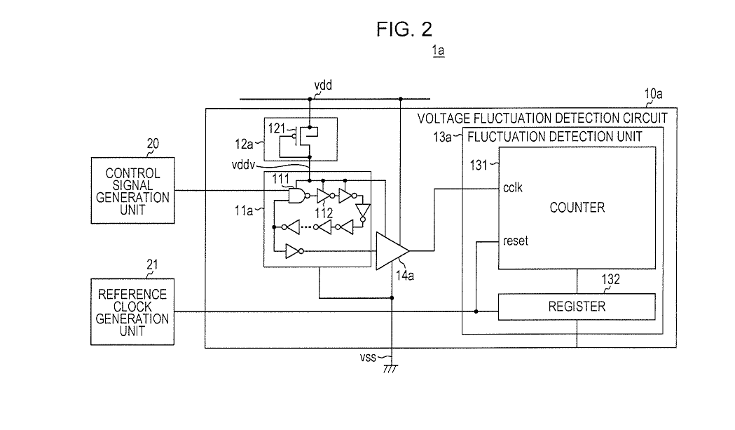

FIG. 2 illustrates examples of a semiconductor integrated circuit and a voltage fluctuation detection circuit according to a second embodiment.

A semiconductor integrated circuit is includes the wiring (e.g., power supply wiring) vdd, the wiring (e.g., grounding wire) vss, a voltage fluctuation detection circuit 10a, a control signal generation unit 20, and a reference clock generation unit 21. In the example of the semiconductor integrated circuit 1a, and according to the second embodiment, the wiring vdd is set as the power supply potential, and the wiring vss is set as the reference potential (e.g., grounding potential).

The voltage fluctuation detection circuit 10a includes an oscillation circuit 11a, an operation voltage generation unit 12a, a fluctuation detection unit 13a, and a level shifter 14a.

The oscillation circuit 11a functions as a ring oscillator having an oscillation control function and includes a NAND circuit 111 and plural inverter circuits 112. A control signal from the control signal generation unit 20 is input to one of input terminals of the NAND circuit 111, and the oscillation in the ring oscillator is controlled in accordance with a value of the control signal. For simplicity, the NAND circuit 111 and a part of the inverter circuits 112 of FIG. 2 are connected to the operation voltage generation unit 12a; however, the NAND circuit 111 and the respective inverter circuits 112 may be supplied with power supply voltage where the voltage is reduced by the operation voltage generation unit 12a. Further, the wiring vss is connected to the NAND circuit 111 and the respective inverter circuits 112, even though it is not illustrated as such in FIG. 2.

The oscillation circuit 11a, having aspects as described above, is configured to receive an operation voltage generated by the operation voltage generation unit 12a and perform an oscillation operation when the control signal is “1”. In an aspect, the output of the NAND circuit 111 is fixed as “1” when the control signal is “0”, and the oscillation operation is not conducted. An oscillation frequency of the oscillation circuit 11a is adjusted, for example, on the basis of the number of poles of the inverter circuits 112.

The oscillation circuit 11a is not particularly limited to the ring oscillator, and it suffices if the oscillation circuit 11a receives the operation voltage and performs the oscillation operation.

In the example of the voltage fluctuation detection circuit 10, and according to the second embodiment, the operation voltage generation unit 12a is connected to the wiring vdd and configured to reduce the power supply voltage to generate the operation voltages of the oscillation circuit 11a and the level shifter 14a. In the example of the voltage fluctuation detection circuit 10a according to the second embodiment, the operation voltage generation unit 12a functions as a voltage lower control circuit configured to reduce the power supply voltage. As illustrated in FIG. 2, and in an aspect, the operation voltage generation unit 12a includes a diode-connected p-channel MOSFET (hereinafter, which will be abbreviated as pMOS) 121. A source of the pMOS 121 is connected to the wiring vdd, and a drain is connected to the oscillation circuit 11a and the level shifter 14a. Furthermore, a gate of the pMOS 121 is connected to its own drain, and a back gate is connected to its own source.

The operation voltage generation unit 12a may be, in an aspect, a diode-connected n-channel MOSFET (hereinafter, which will be abbreviated as nMOS). In that case, a drain of the nMOS is connected to the wiring vdd and its own gate, and a source is connected to the oscillation circuit 11a.

The fluctuation detection unit 13a includes a counter 131 and a storage unit 132 (hereinafter, which will also be referred to as a register 132, which is an example of the storage unit).

The counter 131 is configured to count the number of oscillations of the oscillation circuit 11a. As illustrated in FIG. 2, the counter 131 receives the output signal of the oscillation circuit 11a transmitted via the level shifter 14a by a terminal cclk. The counter 131 then counts, for example, the number of rising edges of the output signal within a certain period of time to output the number of oscillations as a count value. The counter 131 receives a reference clock generated in the reference clock generation unit 21 (for example, a system clock) by a terminal reset. The counter 131 then resets the counter value to “0”, for example, when the rise of the reference clock is detected. To elaborate, the count value is reset in every certain period of time (e.g., reference clock cycle).

The register 132 is configured to take in the count value of the counter 131 in synchronism with the reference clock. The register 132 also outputs the taken count value.

The fluctuation detection unit 13a is not particularly limited to the aspects as shown in, and described with respect to, FIG. 2, and it suffices if the fluctuation detection unit 13a can detect the fluctuation of the oscillation frequency.

The level shifter 14a is configured to adjust the amplitude of the output signal of the oscillation circuit 11a in accordance with the amplitude of the operation voltage of the fluctuation detection unit 13a. In the example of the voltage fluctuation detection circuit 10a, and according to the second embodiment, the fluctuation detection unit 13a is operated at the potential level of the wiring vdd. For that reason, the level shifter 14a is connected to the wiring vdd and configured to change the signal level of the output signal of the oscillation circuit 11a to the potential level of the wiring vdd. Accordingly, the fluctuation detection unit 13a can accurately detect the oscillation frequency. For example, the fluctuation detection unit 13a is also operated at the signal level of the output signal of the oscillation circuit 11a and can detect the output signal of the oscillation circuit 11a. As such, the level shifter 14a may be omitted.

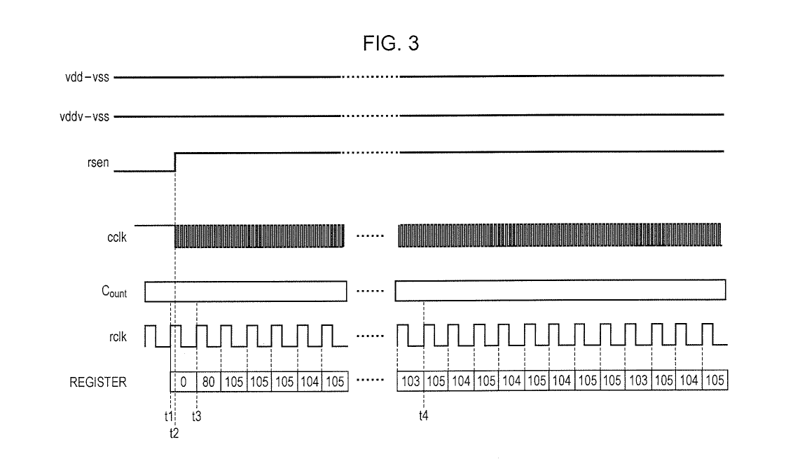

FIG. 3 is a timing chart that illustrates an example of a first operation of the voltage fluctuation detection circuit according to the second embodiment.

FIG. 3 illustrates states of a potential difference between the wiring vdd and the wiring vss, a potential difference between a wiring vddv, which is connected between the operation voltage generation unit 12a and the oscillation circuit 11a, and the wiring vss, and a control signal rsen generated by the control signal generation unit 20. Furthermore, a potential of the terminal cclk of the counter 131 (e.g., potential of the output signal of the level shifter 14a), a potential of the count value Cₒᵤₙₜ of the counter 131, a potential of a terminal rclk of the counter 131 (e.g., potential of the reference clock), and a value of the register 132 are illustrated. For simplicity, an example of the value of the count value Cₒᵤₙₜ is omitted in the example of FIG. 3.

When the control signal rsen is at an L (Low) level, the oscillation circuit 11a does not oscillate, and the potential of the terminal cclk is fixed at an H (High) level. For that reason, the count value Cₒᵤₙₜ is “0”, and when the potential of the terminal rclk rises (timing t1), the register 132 takes in “0”.

When the control signal rsen rises to the H level (timing t2), the oscillation circuit 11a starts the oscillation. Accordingly, the counter 131 counts the rising edges of the potential of the terminal cclk. The register 132 then takes in the count value Cₒᵤₙₜ (“80” in the example of FIG. 3) in synchronization with the rising timing of the potential of the terminal rclk (timing t3). Hereinafter, a similar operation is conducted.

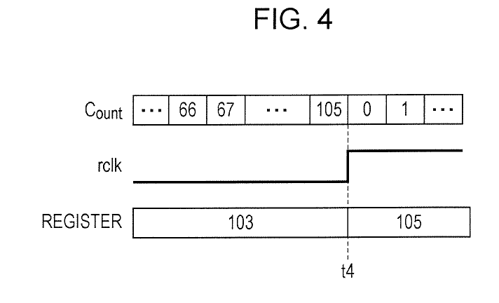

FIG. 4 is a partially enlarged view of the timing chart of FIG. 3, which shows a state at the timing t4.

The count value Cₒᵤₙₜ, which is currently “105”, is reset to “0” at the rising timing t4 of the potential of the terminal rclk, and taken in by the register 132.

For example, in a case where no noise exists and the potential between the wiring vdd and the wiring vss (e.g., power supply voltage) hardly fluctuates (e.g., as in FIG. 3), the count value Cₒᵤₙₜ stored in the register 132 takes almost the same value.

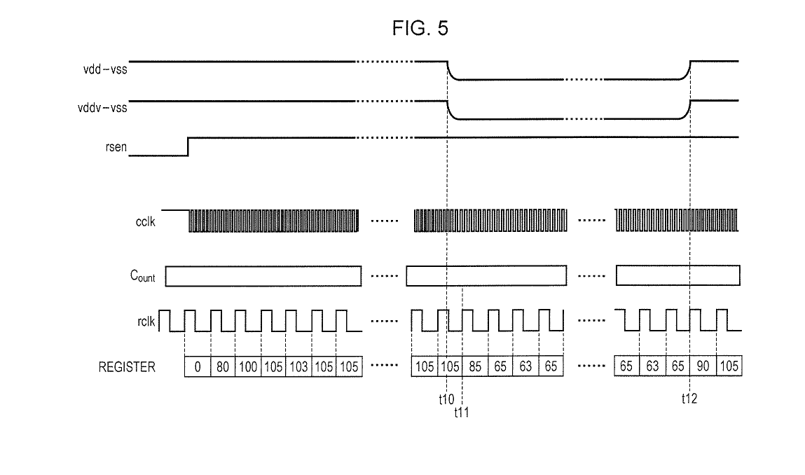

FIG. 5 is a timing chart that illustrates a second example operation of the voltage fluctuation detection circuit according to the second embodiment. The signals illustrated in FIG. 5 are of the same type as those illustrated in FIG. 3.

In the example of FIG. 5, the potential between the wiring vdd and the wiring vss is decreased (e.g., voltage drop occurs) because of the influence of, for example, the power supply noise between the timings t10 and t12.

At this time, the potential difference between the wiring vddv and the wiring vss is also decreased, and the oscillation frequency of the oscillation circuit 11a is decreased in response to this change. Accordingly, the count value Cₒᵤₙₜ between the rise of the potential of the terminal rclk and the next rise is low. In the example of FIG. 5, the count value Cₒᵤₙₜ taken in by the register 132, when the potential of the terminal rclk rises at the timing t11, is decreased from “105” to “85”. When the potential between the wiring vdd and the wiring vss returns to the original state at the timing t12, the potential difference between the wiring vddv and the wiring vss and the oscillation frequency of the oscillation circuit 11a also return to their respective original states. According to this, the count value Cₒᵤₙₜ is also returned from “65” to “90” and “105”, which were the values of Cₒᵤₙₜ at the timing t10 or before.

The count value Cₒᵤₙₜ taken in by the register 132 is output, for example, from an external terminal (not illustrated) of the semiconductor integrated circuit 1a as the information on the plural bits, in synchronism with the reference clock. For example, the fluctuation of the power supply voltage can be detected by detecting the change of the output count value Cₒᵤₙₜ.

Hereinafter, effects of the voltage fluctuation detection circuit 10a according to the second embodiment will be described.

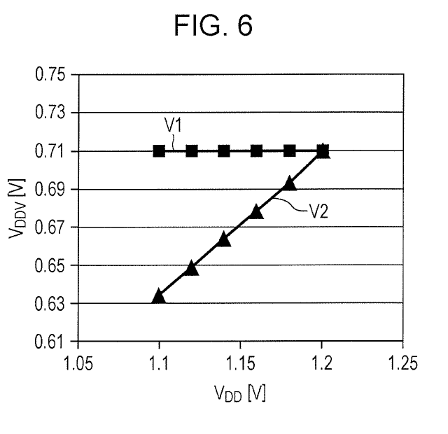

FIG. 6 illustrates results of a simulation for the power supply voltage V_{DD} dependency of the operation voltage V_{DDv} [V] of the oscillation circuit due to a difference in PSRR of the operation voltage generation unit. The vertical axis represents the operation voltage V_{DDv} [V] of the oscillation circuit, and the horizontal axis represents the power supply voltage V_{DD} [V].

As a simulation condition, the steady state value of the oscillation frequency when the power supply voltage V_{DD} is 1.2 V is set as approximately 256 MHz. A simulation result V1 represents the power supply voltage V_{DD} dependency of the operation voltage V_{DDv} in a case where the PSRR of the operation voltage generation unit 12a is supposed to be set as 100. A simulation result V2 represents the power supply voltage V_{DD} dependency of the operation voltage V_{DDV} in a case where the operation voltage generation unit 12a (e.g., PSRR≈1.3) to which the pMOS 121 illustrated in FIG. 2 is adopted.

As represented in the simulation result V1, if the PSRR is high, even when the power supply voltage V_{DD} is changed, the operation voltage V_{DDv} hardly changes. In contrast, the fluctuation of the power supply voltage V_{DD} affects the operation voltage V_{DDv} in the simulation result V2 to which the operation voltage generation unit 12a having the low PSRR is applied. In addition, as represented in the simulation result V2, the operation voltage generation unit 12a can reduce the voltage from the power supply voltage V_{DD}=1.2 [V] to the operation voltage V_{DDv}=approximately 0.7 V, even having the low PSRR.

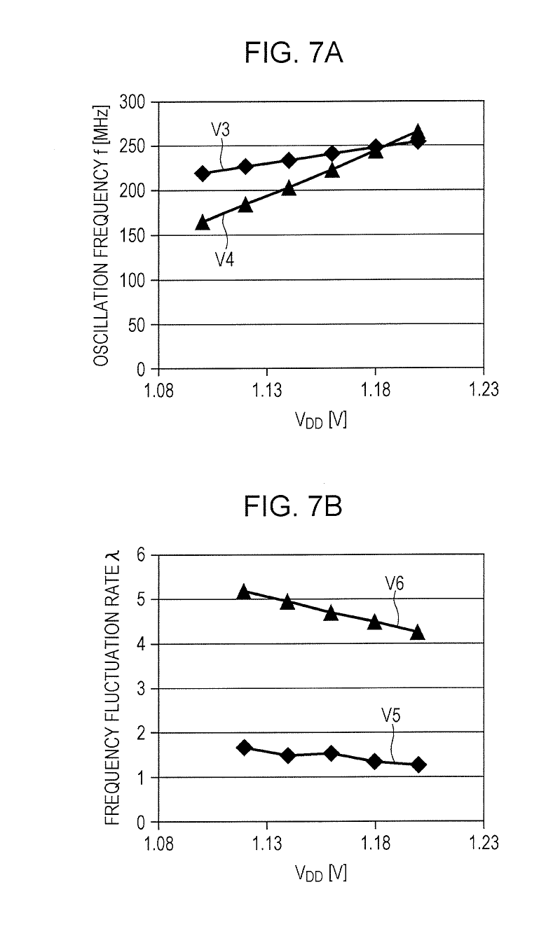

FIG. 7A illustrates a result of a simulation regarding the power supply voltage V_{DD} dependency of the oscillation frequency f of the oscillation circuit depending on the presence or absence of the operation voltage generation unit. FIG. 7B illustrates a result of a simulation regarding the power supply voltage V_{DD} dependency of the oscillation frequency fluctuation rate λ depending on the presence or absence of the operation voltage generation unit. In FIG. 7A, the horizontal axis represents the power supply voltage V_{DD} [V], and the vertical axis represents the oscillation frequency f [MHz]. In FIG. 7B, the horizontal axis represents the power supply voltage V_{DD} [V], and the vertical axis represents the oscillation frequency fluctuation rate λ.

As a simulation condition, the steady state value of the oscillation frequency when the power supply voltage V_{DD} is 1.2 V is set as approximately 256 MHz.

In FIG. 7A, a simulation result V3 represents the power supply voltage V_{DD} dependency of the oscillation frequency f of the oscillation circuit 11a in a case where the power supply voltage V_{DD} is applied to the oscillation circuit 11a without the provision of the operation voltage generation unit 12a. A simulation result V4 represents the power supply voltage V_{DD} dependency of the oscillation frequency f of the oscillation circuit 11a in a case where the operation voltage generation unit 12a is provided, and the operation voltage V_{DDv} obtained by reducing the power supply voltage V_{DD} is applied to the oscillation circuit 11a.

As represented in the simulation results V3 and V4, when the operation voltage generation unit 12a is provided, there is greater fluctuation of the oscillation frequency f with respect to the change of the power supply voltage V_{DD}.

In FIG. 7B, a simulation result V5 represents the power supply voltage V_{DD} dependency of the oscillation frequency fluctuation rate λ of the oscillation circuit 11a in a case where the power supply voltage V_{DD} is applied to the oscillation circuit 11a without the provision of the operation voltage generation unit 12a. A simulation result V6 represents the power supply voltage V_{DD} dependency of the oscillation frequency fluctuation rate λ of the oscillation circuit 11a in a case where the operation voltage generation unit 12a is provided, and the operation voltage V_{DDv} obtained by reducing the power supply voltage V_{DD} is applied to the oscillation circuit 11a.

As represented in the simulation results V5 and V6, when the operation voltage generation unit 12a is provided, the oscillation frequency fluctuation rate 2 is higher. To elaborate, it is possible to improve the sensitivity for detecting the voltage fluctuation. When the power supply voltage V_{DD} is 1.2 V in a case where the operation voltage generation unit 12a is not provided, the oscillation frequency fluctuation rate 2 is approximately 1.3. In a case where the operation voltage generation unit 12a is provided, the oscillation frequency fluctuation rate λ is approximately 4.3, which is approximately 3.3 times as high as the former rate.

From the relationship of the expression (6), under a condition where the measurement accuracy S is fixed and the operation voltage generation unit 12a is provided, the consumed energy Eₜₒₜₐₗ can be reduced to approximately 30% as compared with the case in which the operation voltage generation unit 12a is not provided.

### Third Embodiment

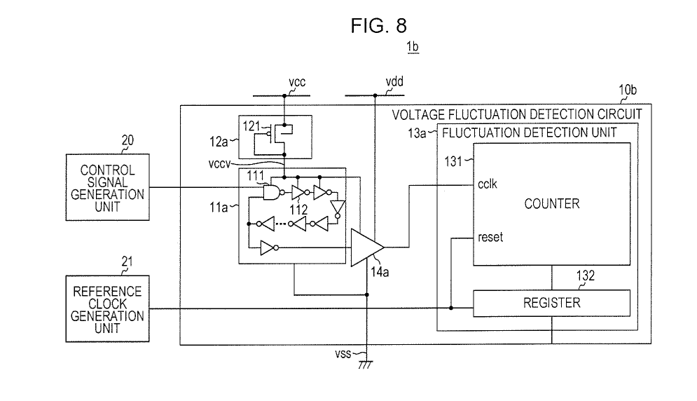

FIG. 8 illustrates examples of a semiconductor integrated circuit and a voltage fluctuation detection circuit according to a third embodiment.

With a semiconductor integrated circuit 1b according to the third embodiment, the operation voltage generation unit 12a of a voltage fluctuation detection circuit 10b is connected to the wiring vcc at an arbitrary potential instead of the wiring vdd at the power supply potential. Accordingly, the operation voltage generation unit 12a is configured to decrease the potential of the wiring vcc and apply the decreased potential difference between the wiring vcc and the wiring vss to the oscillation circuit 11a as an operation voltage V_{CCV} via the wiring vccv. Another configuration is similar to the voltage fluctuation detection circuit 10a according to the second embodiment. The voltage fluctuation detection circuit 10b having aspects configured as described can detect the potential fluctuation of the wiring vcc caused by noise and/or the like.

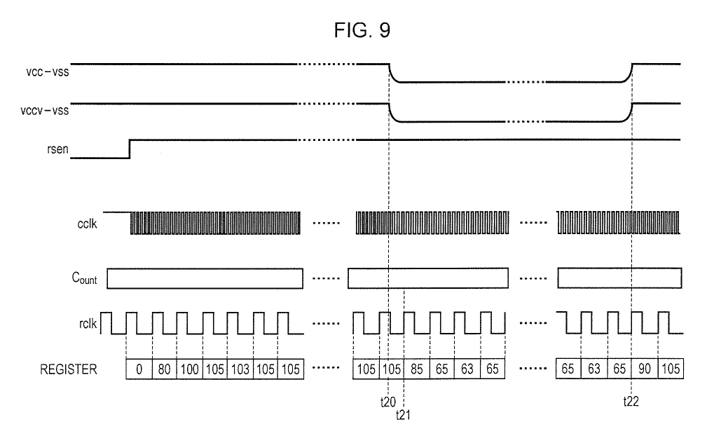

FIG. 9 is a timing chart that illustrates an example operation of the voltage fluctuation detection circuit according to the third embodiment.

FIG. 9 illustrates states of the potential difference between the wiring vcc and the wiring vss, the potential difference between a wiring vccv, between the operation voltage generation unit 12a and the oscillation circuit 11a, and the wiring vss, and the control signal rsen generated in the control signal generation unit 20. Furthermore, the potential of the terminal cclk of the counter 131 (e.g., potential of the output signal of the level shifter 14a), the count value Cₒᵤₙₜ of the counter 131, the potential of the terminal rclk of the counter 131 (e.g., potential of the reference clock), and the value of the register 132 are illustrated. For simplicity, an example of the value of the count C is omitted in the example of FIG. 9.

In the example of FIG. 9, the potential difference between the wiring vcc and the wiring vss is decreased (e.g., voltage drop occurs) because of the influence of, for example, the power supply noise between the timings t20 and t22.

The potential difference between the wiring vccv and the wiring vss is also decreased, and the oscillation frequency of the oscillation circuit 11a is shortened in response to this change. Accordingly, the count value Cₒᵤₙₜ between the rise of the potential of the terminal rclk and the next rise is low. In the example of FIG. 9, the count value Cₒᵤₙₜ taken into the register 132, when the potential of the terminal rclk rises, is decreased from “105” to “85” at the timing t21. When the potential difference between the wiring vcc and the wiring vss returns to the original state at the timing t22, the potential difference between the wiring vccv and the wiring vss and the oscillation frequency of the oscillation circuit 11a also return to their respective original states. Accordingly, the count value Cₒᵤₙₜ also returns its value from “65” to “90” and “105”, which were the values at the timing t20 or before.

The count value Cₒᵤₙₜ taken in by the register 132 is output, for example, from an external terminal (not illustrated) of the semiconductor integrated circuit 1b as the information on the plural bits, in synchronism with the reference clock. For example, the fluctuation of the potential difference between the wiring vcc and the wiring vss may be detected by detecting the change of the output count value Cₒᵤₙₜ.

Hereinafter, effects of the voltage fluctuation detection circuit 10b according to the third embodiment will be described.

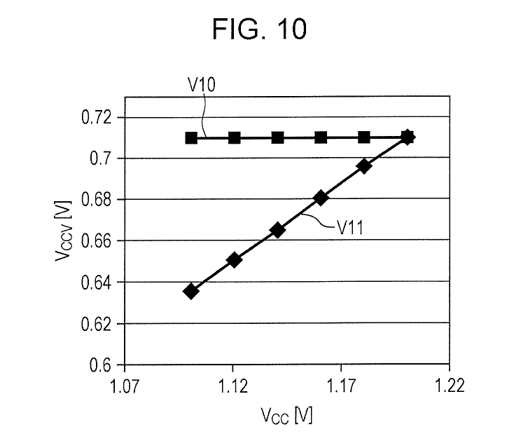

FIG. 10 illustrates a result of an example simulation for the voltage V_{CC} dependency of the operation voltage V_{CCV} of the oscillation circuit due to a difference in PSRR of the operation voltage generation unit. The vertical axis represents the operation voltage V_{CCV} [V] of the oscillation circuit, and the horizontal axis represents a voltage V_{CC} [V] between the wiring vcc and the wiring vss.

As a simulation condition, the steady state value of the oscillation frequency when the voltage V_{CC} and the power supply voltage V_{DD} are 1.2 V is set as approximately 256 MHz. A simulation result V10 represents the voltage V_{CC} dependency of the operation voltage V_{CCV} of the oscillation circuit 11a in a case where the PSRR of the operation voltage generation unit 12a is supposed to be set as 100. A simulation result V11 represents the voltage V_{CC} dependency of the operation voltage V_{CCV} of the oscillation circuit 11a in a case where the operation voltage generation unit 12a (e.g., PSRR 1.3) to which the pMOS 121 illustrated in FIG. 8 is applied.

As represented in the simulation result V10, when the PSRR is high, even if the voltage V_{CC} changes, the operation voltage V_{CCV} hardly changes. In contrast to this, in the simulation result V11 to which the operation voltage generation unit 12a having the low PSRR is applied, the fluctuation of the voltage Vcc affects the operation voltage V_{CCV}. In addition, as represented in the simulation result V11, even if the operation voltage generation unit 12a has the low PSRR, it can reduce the voltage from the voltage V_{CC}=1.2 [V] to the operation voltage V_{CCV}=approximately 0.7 V.

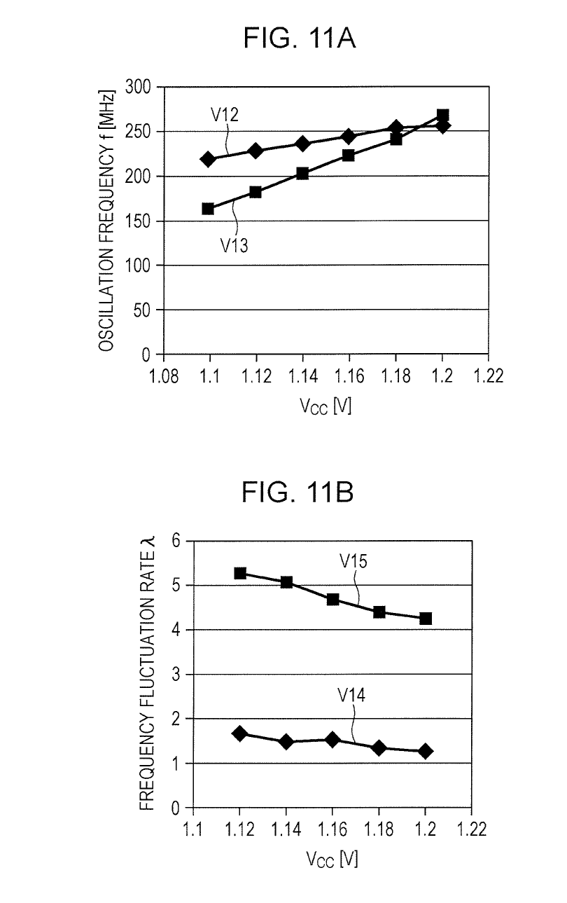

FIG. 11A illustrates a result of an example simulation regarding the voltage V_{CC} dependency of the oscillation frequency f of the oscillation circuit depending on the presence or absence of the operation voltage generation unit. FIG. 11B illustrates a result of an example simulation regarding the voltage V_{CC} dependency of the oscillation frequency fluctuation rate λ depending on the presence or absence of the operation voltage generation unit. In FIG. 11A, the horizontal axis represents the voltage V_{CC} [V], and the vertical axis represents the oscillation frequency f [MHz]. In FIG. 11B, the horizontal axis represents the voltage V_{CC} [V], and the vertical axis represents the oscillation frequency fluctuation rate λ.

As a simulation condition, the steady state value of the oscillation frequency when the voltage V_{CC} and the power supply voltage V_{DD} are 1.2 V is set as approximately 256 MHz.

In FIG. 11A, a simulation result V12 represents the voltage V_{CC} dependency of the oscillation frequency f of the oscillation circuit 11a in a case where the voltage V_{CC} is applied to the oscillation circuit 11a without the provision of the operation voltage generation unit 12a. A simulation result V13 represents the voltage V_{CC} dependency of the oscillation frequency f of the oscillation circuit 11a in a case where the operation voltage generation unit 12a is provided and the operation voltage V_{CCV} obtained by reducing the voltage V_{CC} is applied to the oscillation circuit 11a.

As represented in the simulation results V12 and V13, the oscillation frequency f fluctuates to a larger extent with respect to the change of the voltage Vcc when the operation voltage generation unit 12a is provided.

In FIG. 11B, a simulation result V14 represents the voltage V_{CC} dependency of the oscillation frequency fluctuation rate λ of the oscillation circuit 11a in a case where the voltage V_{CC} is applied to the oscillation circuit 11a without the provision of the operation voltage generation unit 12a. A simulation result V15 represents the voltage V_{CC} dependency of the oscillation frequency fluctuation rate λ of the oscillation circuit 11a in a case where the operation voltage generation unit 12a is provided and the operation voltage V_{CCV}, obtained by reducing the voltage V_{CC}, is applied to the oscillation circuit 11a.

As represented in the simulation results V14 and V15, when the operation voltage generation unit 12a is provided, the oscillation frequency fluctuation rate λ is higher. To elaborate, it is possible to improve the sensitivity for detecting the voltage fluctuation. When the voltage V_{CC} is 1.2 V, and in a case where the operation voltage generation unit 12a is not provided, the oscillation frequency fluctuation rate 2 is approximately 1.3. In a case where the operation voltage generation unit 12 is provided, the oscillation frequency fluctuation rate λ is approximately 4.3, which is approximately 3.3 times as high as the former rate.

From the expression (6) where the power supply voltage V_{DD} is replaced by the voltage V_{CC}, under a condition where the measurement accuracy S is fixed and the operation voltage generation unit 12a is provided, the consumed energy Eₜₒₜₐₗ can be reduced to approximately 30% as compared with the case in which the operation voltage generation unit 12a is not provided.

In this manner, with the voltage fluctuation detection circuit 10b, similarly as in the case of detecting the fluctuation of the power supply voltage, it is possible to improve the sensitivity at which the voltage fluctuation is detected. Also, the consumed energy Eₜₒₜₐₗ can be reduced, so that it is possible to reduce the power consumption.

### Fourth Embodiment

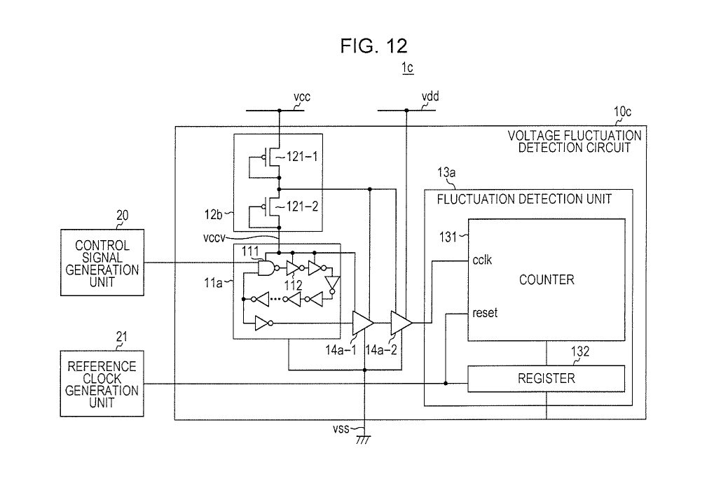

FIG. 12 illustrates examples of a semiconductor integrated circuit and a voltage fluctuation detection circuit according to a fourth embodiment. Elements similar to those of the voltage fluctuation detection circuit 10b according to the third embodiment are assigned the same reference symbols.

With a semiconductor integrated circuit 1c according to the fourth embodiment, an operation voltage generation unit 12b of a voltage fluctuation detection circuit 10c includes two diode-connected pMOSs 121-1 and 121-2. The operation voltage generation unit 12b may be configured to further reduce the potential of the wiring vccas compared with other embodiments and aspects. Accordingly, since the operation voltage V_{CCV} of the oscillation circuit 11a can be further reduced, it is possible to further increase the oscillation frequency fluctuation rate λ of the oscillation circuit 11a. To elaborate, it is possible to further improve the sensitivity at which the voltage fluctuation is detected.

Two level shifters 14a-1 and 14a-2 are also provided. The level shifter 14a-1 is connected to the oscillation circuit 11a, drains of the pMOSs 121-1 and 121-2, and the wiring vss. The level shifter 14a-1 is configured to increase the potential level (e.g., amplitude) of the output signal of the oscillation circuit 11a from the potential level of the operation voltage V_{CCV} to the potential level of the drain of the pMOS 121-1. The level shifter 14a-2 is connected to an output terminal of the level shifter 14a-1, the drain of the pMOS 121-1, and the wirings vdd and vss. The level shifter 14a-2 is configured to increase the potential level of the output signal from the level shifter 14a-1 from the potential level of the drain of the pMOS 121-1 to the potential level of the wiring vdd (e.g., power supply potential).

In a case where the single level shifter 14a is used, if the potential difference between the power supply potential and the wiring vccv is too large, a concern exists that the level shifter 14a may not operate; however, the problem can be addressed with the provision of the plural level shifters 14a-1 and 14a-2.

Since the operation of the voltage fluctuation detection circuit 10c is similar to the operation of the voltage fluctuation detection circuit 10b according to the third embodiment (see FIG. 9 or the like), the description thereof will be omitted.

Hereinafter, effects of the voltage fluctuation detection circuit 10c according to the fourth embodiment will be described.

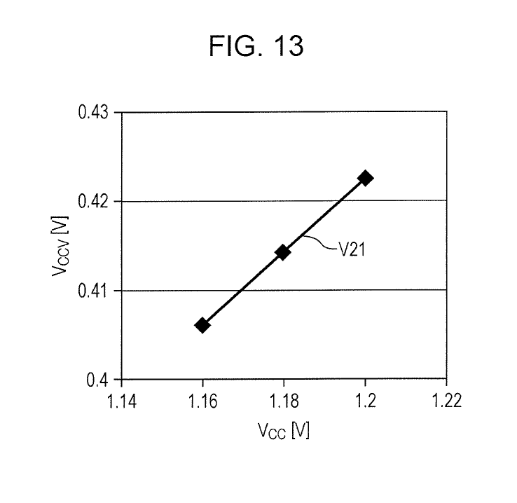

FIG. 13 illustrates a result of an example simulation for the voltage V_{CC} dependency of the operation voltage V_{CCV} of the oscillation circuit in the fluctuation detection circuit according to the fourth embodiment. The vertical axis represents the operation voltage V_{CCV} [V] of the oscillation circuit, and the horizontal axis represents the voltage V_{CC} [V] between the wiring vcc and the wiring vss.

As a simulation condition, the steady state value of the oscillation frequency, when the voltage V_{CC} and the power supply voltage V_{DD} are 1.2 V, is set as approximately 70 MHz. A simulation result V21 represents the voltage V_{CC} dependency of the operation voltage V_{CCV} of the oscillation circuit 11a that adopts the operation voltage generation unit 12b (e.g., PSRR≈2.5) to which the pMOSs 121-1 and 121-2 illustrated in FIG. 12 are applied.

As represented in the simulation result V21, the fluctuation of the voltage V_{CC} affects the operation voltage V_{CCV}. Furthermore, when the voltage V_{CC}=1.2 [V], the operation voltage V_{CCV}=approximately 0.42 V, and the voltage is reduced to a larger extent than it is for the voltage fluctuation detection circuits 10a and 10b according to the second and third embodiments.

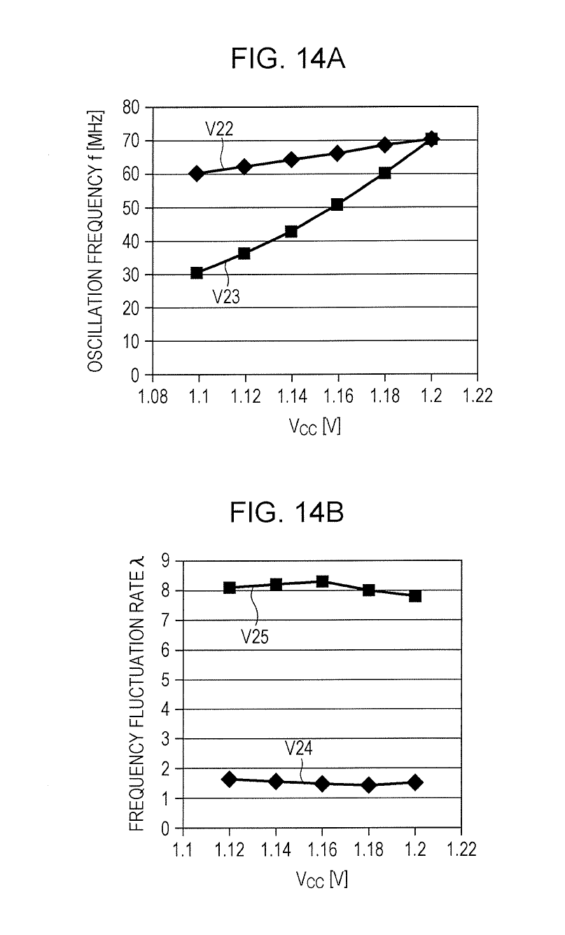

FIG. 14A illustrates a result of an example simulation regarding the voltage V_{CC} dependency of the oscillation frequency f of the oscillation circuit depending on the presence or absence of the operation voltage generation unit. FIG. 14B illustrates a simulation result regarding the voltage V_{CC} dependency of the oscillation frequency fluctuation rate λ depending on the presence or absence of the operation voltage generation unit. In FIG. 14A, the horizontal axis represents the voltage V_{CC} [V], and the vertical axis represents the oscillation frequency f [MHz]. In FIG. 14B, the horizontal axis represents the voltage V_{CC} [V], and the vertical axis represents the oscillation frequency fluctuation rate λ.

As a simulation condition, the steady state value of the oscillation frequency when the voltage V_{CC} and the power supply voltage V_{DD} are 1.2 V is set as approximately 70 MHz.

In FIG. 14A, a simulation result V22 represents the voltage V_{CC} dependency of the oscillation frequency f of the oscillation circuit 11a in a case where the voltage V_{CC} is applied to the oscillation circuit 11a without the provision of the operation voltage generation unit 12b. A simulation result V23 represents the voltage V_{CC} dependency of the oscillation frequency f of the oscillation circuit 11a in a case where the operation voltage generation unit 12b is provided and the operation voltage V_{CCV} obtained by reducing the voltage V_{CC} is applied to the oscillation circuit 11a.

As represented in the simulation result V22 and V23, the state where the oscillation frequency f fluctuates to a larger extent with respect to the change of the voltage V_{CC}, and if the operation voltage generation unit 12b is provided, is the same as for the voltage fluctuation detection circuits 10a and 10b according to the above-mentioned second and third embodiments.

In FIG. 14B, a simulation result V24 represents the voltage V_{CC} dependency of the oscillation frequency fluctuation rate λ of the oscillation circuit 11a in a case where the voltage V_{CC} is applied to the oscillation circuit 11a without the provision of the operation voltage generation unit 12b. A simulation result V25 represents the voltage V_{CC} dependency of the oscillation frequency fluctuation rate λ of the oscillation circuit 11a in a case where the operation voltage generation unit 12b is provided and the operation voltage V_{CCV} obtained by reducing the voltage V_{CC} is applied to the oscillation circuit 11a.

As represented in the simulation result V24 and V25, the oscillation frequency fluctuation rate λ is higher when the operation voltage generation unit 12b is provided, as it is for the voltage fluctuation detection circuits 10a and 10b according to the above-mentioned second and third embodiments. Furthermore, in the voltage fluctuation detection circuit 10c according to the fourth embodiment, and in a case where the operation voltage generation unit 12b is provided, the voltage V_{CC} is 1.2 V, the oscillation frequency fluctuation rate λ is approximately 7.8. This corresponds to approximately 5.6 times higher than the oscillation frequency fluctuation rate λ (e.g., approximately 1.4) in a case where the operation voltage generation unit 12b is not provided. This value is higher than that for the voltage fluctuation detection circuits 10a and 10b according to the above-mentioned second and third embodiments. To elaborate, it is possible to further improve the sensitivity at which the voltage fluctuation is detected.

From the relationship of the expression (6) where the power supply voltage V_{DD} is replaced by the voltage V_{CC}, under a condition where the measurement accuracy S is fixed and the operation voltage generation unit 12b is provided, the consumed energy Eₜₒₜₐₗ can be reduced to approximately 18% as compared with the case in which the operation voltage generation unit 12b is not provided.

In this manner, the potential of the wiring vcc is reduced to a larger extent by the pMOSs 121-1 and 121-2, and the operation voltage of the oscillation circuit 11a is reduced in the voltage fluctuation detection circuit 10c. Accordingly, it is possible to improve the sensitivity at which the voltage fluctuation is detected, and also the power consumption can be reduced to a larger extent as compared with that of the voltage fluctuation detection circuits 10a and 10b according to the second and third embodiments.

In the above-mentioned example of the voltage fluctuation detection circuit 10c, since the operation voltage of the oscillation circuit 11a is further decreased, an upper limit value of the oscillation frequency is decreased. For that reason, the configuration may be desirably applied to a case where the oscillation frequency may be low (for example, a case where a period of time in which the voltage fluctuation is generated is long).

The case has been described in which the pMOSs 121-1 and 121-2 are provided in the two poles in the voltage fluctuation detection circuit 10c; however, the pMOSs 121-1 and 121-2 may be provided in three or more poles, and the level shifters 14a-1 and 14a-2 may also be provided in three or more corresponding poles. In an aspect, the diode-connected nMOSs may be used in plural poles instead of the pMOS.

### Fifth Embodiment

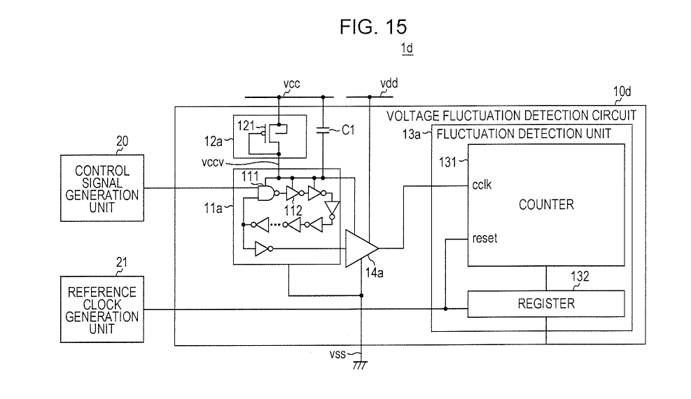

FIG. 15 illustrates examples of a semiconductor integrated circuit and a voltage fluctuation detection circuit according to a fifth embodiment. Elements similar to the elements of the voltage fluctuation detection circuit 10b according to the third embodiment are assigned with the same reference symbols.

In the semiconductor integrated circuit 1d according to the fifth embodiment, and in a voltage fluctuation detection circuit 10d, a capacitative element C1 is connected between the wiring vccv (e.g., wiring for applying the operation voltage to the oscillation circuit 11a), arranged between the operation voltage generation unit 12a and the oscillation circuit 11a, and the wiring vcc. The capacitative element C1 functions as a coupling capacitance. With the provision of the capacitative element C1, it is possible to decrease the transient PSRR as compared with the case in which the capacitative element C1 is not provided. From the expression (8), since the oscillation frequency fluctuation rate can be increased if the PSRR can be decreased, it is possible to improve the sensitivity for detecting the voltage fluctuation. For that reason, the high accuracy detection of the voltage fluctuation can be conducted, and from the expression (6), in a case where the measurement accuracy S is fixed, it is possible to reduce the consumed energy Eₜₒₜₐₗ.

Since the operation of the voltage fluctuation detection circuit 10d is similar to the operation of the voltage fluctuation detection circuit 10b according to the third embodiment, the description thereof will be omitted.

Hereinafter, a description will be given as to how the PSRR can be decreased further with the provision of the capacitative element C1 as compared to the case where the capacitative element C1 is not arranged.

To observe a transient response of the operation voltage with respect to the voltage drop of the voltage, the operation voltage generation unit 12a and the oscillation circuit 11a are represented by a resistance component and a capacitance component as follows.

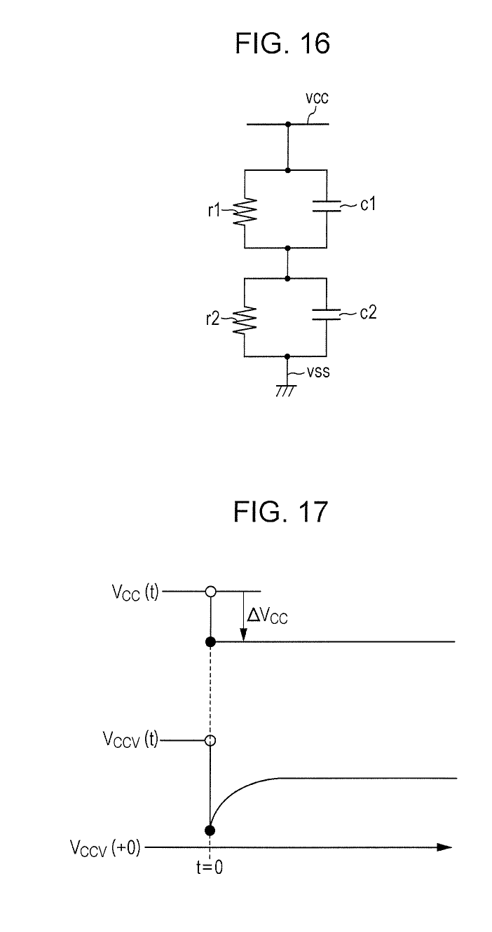

FIG. 16 is a circuit where the operation voltage generation unit and the oscillation circuit are represented by the resistance component and the capacitance component.

A parallel circuit composed of a resistance r1 and a capacitance c1 and a parallel circuit composed of a resistance r2 and a capacitance c2 are connected between the wiring vcc and the wiring vss.

The resistance r1 represents a resistance component of the operation voltage generation unit 12a, and the capacitance c1 is the same as or similar to the capacitative element C1 of FIG. 15. The resistance r2 is a resistance component of the oscillation circuit 11a, and the capacitance c2 represents a capacitance component of the oscillation circuit 11a.

In the following description, which is one example, a resistance value of the resistance r1 is set as R_{PSW}, a capacitance value of the capacitance c1 (the capacitative element C1) is set as C_{VCCV}, a resistance value of the resistance r2 is set as R_{eff}, and a capacitance value of the capacitance c2 is set as C_{eff}.

FIG. 17 illustrates an example state of a transient response of the voltage Vcc and the operation voltage V_{CCV} of the oscillation circuit. V_{CC}(t) represents a time variation of the voltage V_{CC}, and V_{CCV}(t) represents a time variation of the operation voltage V_{CCV}. FIG. 17 illustrates the state of the transient response of the operation voltage V_{CCV} when the voltage drop of ΔV_{CC} occurs in the voltage V_{CC} at t=+0 (at a time indicated by a filled-in circle in FIG. 17).

This transient response is represented by the following expression (9).

$$\frac{{V}_{CC} ( t ) - {V}_{CCV} ( t )}{{R}_{PSW}} + \frac{\partial ( {C}_{VCCV} ( {V}_{CC} ( t ) - {V}_{CCV} ( t ) ) )}{\partial t} - \frac{{V}_{CCV} ( t )}{{R}_{eff}} - \frac{\partial ( {C}_{eff} {V}_{CCV} ( t ) )}{\partial t} = 0 \\ {V}_{CC} ( t ) ≡ {V}_{CC} ( - 0 ) - Δ {V}_{CC} \cdot u ( t ) \\ {V}_{CCV } ( t < 0 ) = \frac{{R}_{eff}}{{R}_{PSW} + {R}_{eff}} \cdot {V}_{CC} = {V}_{CCV} ( - 0 ) \qquad ( 9 )$$

In the expression (9), V_{CC} (−0) is a value of the voltage V_{CC} at t=−0 (at a time indicated by an open circle in FIG. 17). u(t) is a unit step function.

When V_{CCV}(t) in the expression (9) is solved by using Laplace transformation, the following expression is obtained.

$$\frac{\partial {V}_{CC}}{\partial t} = - Δ {V}_{CC} \cdot δ ( t ) ⇒ L ( \frac{\partial {V}_{CC}}{\partial t} ) = - Δ {V}_{CC} \\ L ( \frac{\partial {V}_{CCV}}{\partial t} ) = s \cdot {V}_{CCV} ( s ) - {V}_{CCV} ( - 0 ) \\ ⇒ \frac{{V}_{CC} ( s ) - {V}_{CCV} ( s )}{{R}_{PSW}} + {C}_{VCCV} ( - Δ {V}_{CC} - s \cdot {V}_{CCV} ( s ) + {V}_{CCV} ( - 0 ) ) - \frac{{V}_{CCV} ( s )}{{R}_{eff}} - {C}_{eff} \cdot ( s \cdot {V}_{CCV} ( s ) - {V}_{CCV} ( - 0 ) ) = 0 \\ ⇒ {V}_{CCV} ( s ) = \frac{1}{( 1 + \frac{{R}_{PSW}}{{R}_{eff}} + s \cdot {R}_{PSW} \cdot ( {C}_{VCCV} + {C}_{eff} ) )} \cdot ( \begin{matrix}\frac{{V}_{CC} ( - 0 ) - Δ {V}_{CC}}{s} + {R}_{PSW} \cdot \\ ( ( {C}_{VCCV} + {C}_{eff} ) \cdot {V}_{CCV} ( - 0 ) - {C}_{VCCV} \cdot Δ {V}_{CC} )\end{matrix} ) \\ ⇒ {V}_{CCV} ( t ) = ( \frac{{R}_{eff}}{{R}_{eff} + {R}_{PSW}} - \frac{{C}_{VCCV}}{{C}_{VCCV} + {C}_{eff}} ) \cdot Δ {V}_{CC} \cdot {e}^{- at} + \frac{( {V}_{CC} ( - 0 ) - Δ {V}_{CC} ) \cdot {R}_{eff}}{{R}_{eff} + {R}_{PSW}} \cdot u ( t ) \\ a = \frac{{R}_{eff} + {R}_{PSW}}{{R}_{eff} \cdot {R}_{PSW} \cdot ( {C}_{VCCV} + {C}_{eff} )} \qquad ( 10 )$$

From the result of the expression (10), a value of the operation voltage V_{CCV} at t=+0, V_{CCV}(+0), and a value of the operation voltage V_{CCV} (e.g., convergence value) at t=∞, and V_{CCV}(∞) can be represented by the following expressions (11) and (12).

$$\begin{matrix}{V}_{CCV} ( + 0 ) = {lim}_{s -> ∞} s \cdot {V}_{CCV} ( s ) = \frac{{R}_{eff}}{{R}_{PSW} + {R}_{eff}} \cdot {V}_{CC} ( - 0 ) - \frac{{C}_{VCCV}}{( {C}_{VCCV} + {C}_{eff} )} \cdot Δ {V}_{CC} & ( 11 ) \\ {V}_{CCV} ( ∞ ) = {lim}_{s -> 0} s \cdot {V}_{CCV} ( s ) = \frac{{R}_{eff}}{{R}_{PSW} + {R}_{eff}} \cdot ( {V}_{CC} ( - 0 ) - Δ {V}_{CC} ) & ( 12 )\end{matrix}$$

From the expression (11), it may be understood that as C_{VCCV} corresponding to the capacitance value of the capacitative element C1 is higher, the value of the operation voltage V_{CCV} at t=+0 is lower.

Since ΔV_{CCV}(t) corresponds to the following expression (13), ΔV_{CCV}(+0) and ΔV_{CCV}(∞) can be represented by the expressions (14) and (15).

$$\begin{matrix}Δ {V}_{CCV} ( t ) ≡ {V}_{CCV} ( - 0 ) - {V}_{CCV} ( t ) & ( 13 ) \\ Δ {V}_{CCV} ( + 0 ) = {V}_{CCV} ( - 0 ) - {V}_{CCV} ( + 0 ) = \frac{{C}_{VCCV}}{{C}_{VCCV} + {C}_{eff}} \cdot Δ {V}_{CC} & ( 14 ) \\ Δ {V}_{CCV} ( ∞ ) = {V}_{CCV} ( - 0 ) - {V}_{CCV} ( ∞ ) = \frac{{R}_{eff}}{{R}_{eff} + {R}_{PSW}} \cdot Δ {V}_{CC} & ( 15 )\end{matrix}$$

A period of time until the operation voltage V_{CCV} converges is set as T_{d} (e.g., which is longer as C_{VCCV} is higher), and the PSRR can be represented by the following expression (16).

$$PSRR ≡ \frac{\partial {V}_{CC}}{\partial {V}_{CCV}} \approx \frac{{T}_{d} \cdot Δ {V}_{CC}}{{\int }_{0}^{{T}_{d}} Δ {V}_{CCV} ( t ) d t} \qquad ( 16 )$$

From the expressions (14) to (16), the PSRR at the time of C_{VCCV}=0 and the PSRR at the time of C_{VCCV}>0 can be represented by the following expressions (17) and (18).

$$\begin{matrix}PSRR ( {C}_{VCCV} = 0 ) \approx \frac{2 \cdot Δ {V}_{CC}}{Δ {V}_{CCV} ( ∞ )} = \frac{2 \cdot ( {R}_{eff} + {R}_{PSW} )}{{R}_{eff}} & ( 17 ) \\ PSRR ( {C}_{VCCV} > 0 ) \approx \frac{2 \cdot Δ {V}_{CC}}{Δ {V}_{CCV} ( + 0 ) + Δ {V}_{CCV} ( ∞ )} = \frac{2 \cdot ( {C}_{VCCV} + {C}_{eff} ) \cdot ( {R}_{eff} + {R}_{PSW} )}{{R}_{eff} \cdot ( {C}_{VCCV} + {C}_{eff} ) + {C}_{VCCV} \cdot ( {R}_{eff} + {R}_{PSW} )} & ( 18 )\end{matrix}$$

From the expressions (17) and (18), it may be understood that the PSRR (C_{VCCV}>0)<the PSRR (C_{VCCV}=0) is established, and it may also be understood that as C_{VCCV} is higher, the transiently observed PSRR is lower.

In this manner, and with the provision of the capacitative element C1, the PSRR can be decreased as compared with the case in which the capacitative element C1 is not provided. Since the oscillation frequency fluctuation rate 2, can be increased if the PSRR can be decreased, it is possible to improve the sensitivity at which the voltage fluctuation is detected. Further, the consumed energy Eₜₒₜₐₗ can be reduced, and it is possible to suppress the power consumption.

### Sixth Embodiment

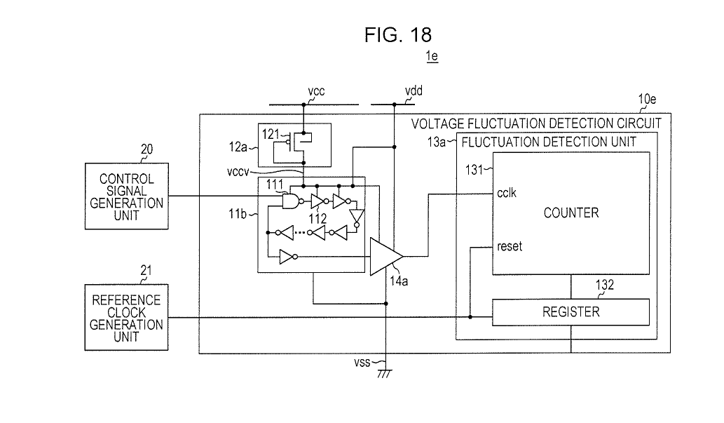

FIG. 18 illustrates examples of a semiconductor integrated circuit and a voltage fluctuation detection circuit according to a sixth embodiment. Elements similar to the elements of the voltage fluctuation detection circuit 10b according to the third embodiment are assigned with the same reference symbols.

In a semiconductor integrated circuit le and a voltage fluctuation detection circuit 10e according to a sixth embodiment, a voltage that is higher than or equal to the operation voltage is applied to an n-well of a pMOS included in an oscillation circuit 11b. For example, the wiring vdd at the power supply potential is electrically connected to the n-well. Although not illustrated in FIG. 18, the pMOS is included in the NAND circuit 111 and the inverter circuits 112.

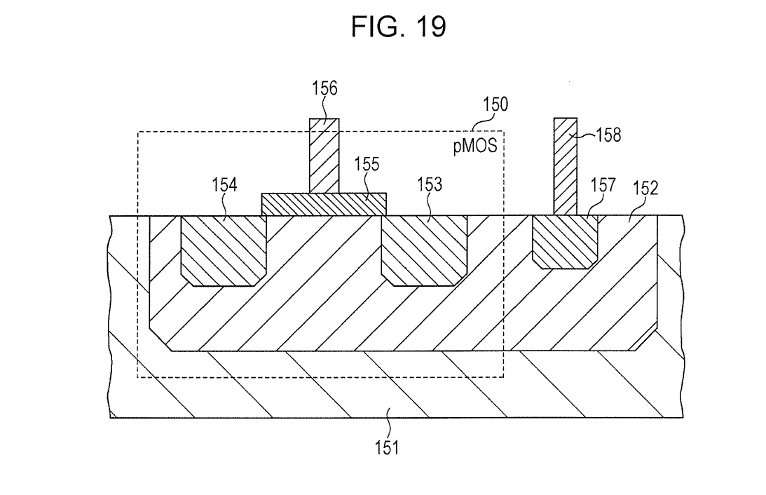

FIG. 19 is a cross sectional view of an example pMOS included in the oscillation circuit.

A pMOS 150 includes an n-well 152 formed on a substrate 151, p-type source/drain regions 153 and 154, a gate oxide film 155 formed so as to stride over the source/drain regions 153 and 154, and a gate electrode 156 formed on the gate oxide film 155. A high concentration n-type layer 157 for contact is formed in the n-well 152, to which a via 158 is connected. The via 158 is connected to the wiring vdd. Accordingly, the n-well 152 is electrically connected to the wiring vdd. The n-well 152 is reversely biased, so that the threshold voltage Vₜₕ of the pMOS 150 is increased.

Since the oscillation frequency fluctuation rate λ can be increased by increasing the threshold voltage Vₜₕ as represented by the expression (7) and understood from the expression (6), and under the condition where the measurement accuracy S is fixed, the consumed energy Eₜₒₜₐₗ can be decreased, and the power consumption can be reduced.

Since the operation of the voltage fluctuation detection circuit 10e is similar to the operation of the voltage fluctuation detection circuit 10b according to the third embodiment, the description thereof will be omitted.

Hereinafter, effects of the voltage fluctuation detection circuit 10e according to the sixth embodiment will be described.

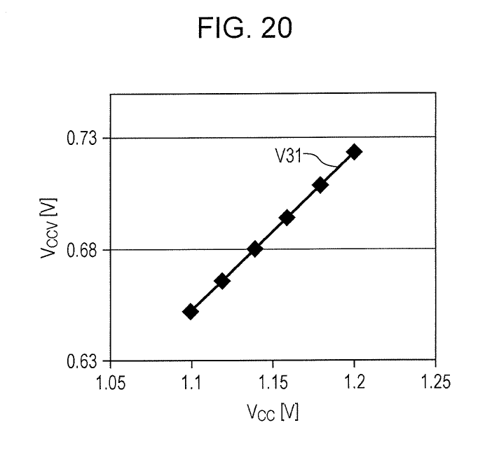

FIG. 20 illustrates a result of an example simulation for the voltage V_{CC} dependency of the operation voltage V_{CCV} of the oscillation circuit in the fluctuation detection circuit according to the sixth embodiment. The vertical axis represents the operation voltage V_{CCV} [V] of the oscillation circuit, and the horizontal axis represents the voltage V_{CC} [V] between the wiring vcc and the wiring vss.

As a simulation condition, when the voltage V_{CC} and the power supply voltage V_{DD} are 1.2 V, the steady state value of the oscillation frequency is set as approximately 256 MHz. A simulation result V31 represents the voltage V_{CC} dependency of the operation voltage V_{CCV} of the oscillation circuit 11b in the case in which the operation voltage generation unit 12a (e.g., PSRR≈1.4) illustrated in FIG. 18 is applied.

As represented in the simulation result V31, the fluctuation of the voltage V_{CC} affects the operation voltage V_{CCV}. Furthermore, when the voltage V_{CC}=1.2 [V], the operation voltage V_{CCV}=approximately 0.7 V is established, and the voltage can be reduced by approximately 0.5 V.

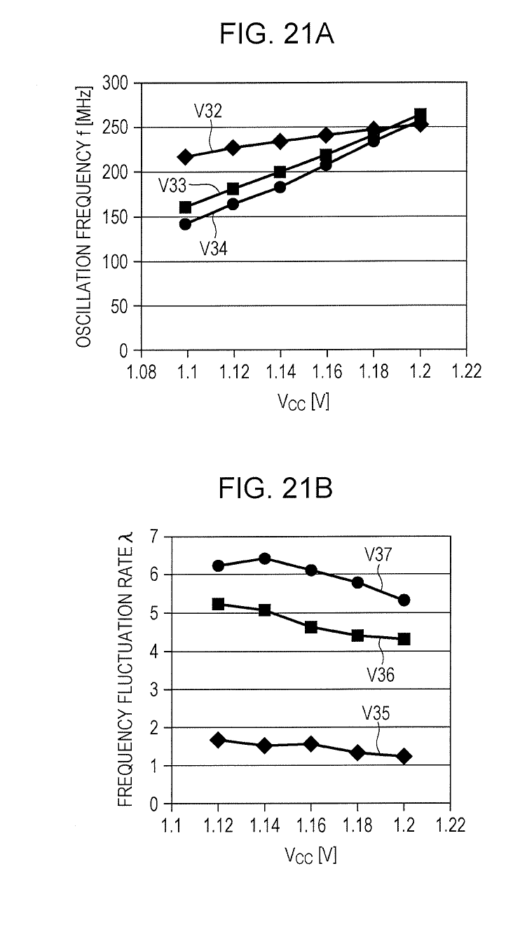

FIG. 21A illustrates a result of an example simulation regarding the voltage V_{CC} dependency of the oscillation frequency f of the oscillation circuit. FIG. 21B illustrates a result of a simulation regarding the voltage V_{CC} dependency of the oscillation frequency fluctuation rate λ. In FIG. 21A, the horizontal axis represents the voltage V_{CC} [V], and the vertical axis represents the oscillation frequency f [MHz]. In FIG. 21B, the horizontal axis represents the voltage V_{CC} [V], and the vertical axis represents the oscillation frequency fluctuation rate λ.

As a simulation condition, when the voltage V_{CC} and the power supply voltage V_{DD} are 1.2 V, the steady state value of the oscillation frequency is set as approximately 256 MHz.

In FIG. 21A, a simulation result V32 represents the voltage V_{CC} dependency of the oscillation frequency f in a case where the voltage V_{CC} is applied to the oscillation circuit lib without the provision of the operation voltage generation unit 12a. As illustrated in FIG. 21A, a simulation result V33 represents the voltage V_{CC} dependency of the oscillation frequency f of the oscillation circuit 11a in a case where the operation voltage generation unit 12a is provided and the operation voltage V_{CCV} obtained by reducing the voltage V_{CC} is applied to the oscillation circuit 11a. As illustrated in FIG. 21A, a simulation result V34 represents the voltage V_{CC} dependency of the oscillation frequency f of the oscillation circuit 11b in a case where the operation voltage generation unit 12a is provided and the wiring vdd is electrically connected to the n-well of the pMOS included in the oscillation circuit 11b.

As represented in the simulation results V32 and V34, and when the operation voltage generation unit 12a is provided, the oscillation frequency f fluctuates to a larger extent with respect to the change of the voltage V_{CC} as compared to the configuration without the provision of the operation voltage generation unit 12a. In addition, as represented in the simulation results V33 and V34, when the wiring vdd is electrically connected to the n-well of the pMOS included in the oscillation circuit 11b, the oscillation frequency f fluctuates to a larger extent with respect to the change of the voltage V_{CC} than the voltage fluctuation detection circuit 10b illustrated in FIG. 8.

In FIG. 21B, a simulation result V35 represents the voltage V_{CC} dependency of the oscillation frequency fluctuation rate λ of the oscillation circuit 11a in a case where the voltage V_{CC} is applied to the oscillation circuit 11a without the provision of the operation voltage generation unit 12a. As illustrated in FIG. 21B, a simulation result V36 represents the voltage V_{CC} dependency of the oscillation frequency fluctuation rate of the oscillation circuit 11a in a case where the operation voltage generation unit 12a is provided and the operation voltage V_{CCV} obtained by reducing the voltage V_{CC} is applied to the oscillation circuit 11a. As illustrated in FIG. 21B, a simulation result V37 represents the voltage V_{CC} dependency of the oscillation frequency fluctuation rate λ of the oscillation circuit 11b in a case where the operation voltage generation unit 12a is provided and the wiring vdd is electrically connected to the n-well of the pMOS included in the oscillation circuit 11b.

As represented in the simulation results V35 and V37, in the voltage fluctuation detection circuit 10e, the oscillation frequency fluctuation rate λ is higher than the configuration without the provision of the operation voltage generation unit 12a. To elaborate, it is possible to improve the sensitivity for detecting the voltage fluctuation. For example, in a case where the operation voltage generation unit 12a is not provided, and when the voltage V_{CC} is 1.2 V, the oscillation frequency fluctuation rate λ is approximately 1.3. Further, the oscillation frequency fluctuation rate λ in the voltage fluctuation detection circuit 10e is approximately 5.4, which is approximately 4.2 times as high as the former rate. Furthermore, as represented in the simulation results V36 and V37, the oscillation frequency fluctuation rate λ is higher than the voltage fluctuation detection circuit 10b illustrated in FIG. 8 in the voltage fluctuation detection circuit 10e.

Therefore, the voltage fluctuation detection circuit 10e can further improve the sensitivity at which the voltage fluctuation is detected as compared with the voltage fluctuation detection circuit 10b. The consumed energy Eₜₒₜₐₗ can also be reduced, so that it is possible to reduce the power consumption.

### Seventh Embodiment

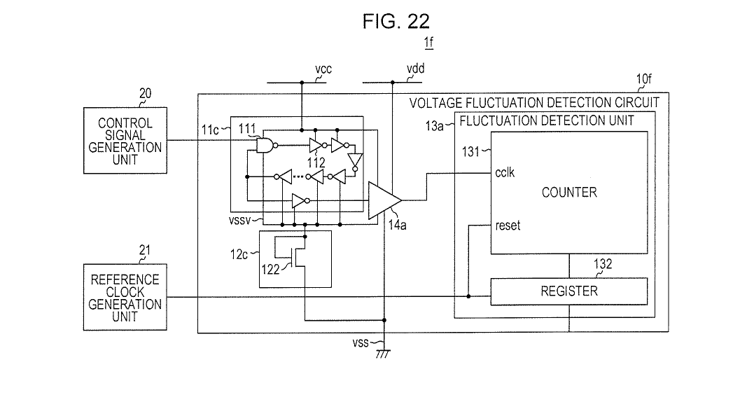

FIG. 22 illustrates examples of a semiconductor integrated circuit and a voltage fluctuation detection circuit according to a seventh embodiment. Elements similar to the elements of the voltage fluctuation detection circuit 10b according to the third embodiment illustrated in FIG. 8 are assigned with the same reference symbols.

In a semiconductor integrated circuit if and a voltage fluctuation detection circuit 10f according to the seventh embodiment, an operation voltage generation unit 12c is connected to the wiring vss that is the reference potential (e.g., grounding potential). The operation voltage generation unit 12c is configured to increase the potential of the wiring vss and reduce the detection target voltage between the wiring vcc and the wiring vss to generate operation voltages of an oscillation circuit 11c and the level shifter 14a. To elaborate, the operation voltage generation unit 12c functions as a boosting circuit configured to increase the grounding potential. As illustrated in FIG. 22, the operation voltage generation unit 12c includes the diode-connected nMOS 122. A source of the nMOS 122 is connected to the wiring vss, and a drain is connected to the oscillation circuit 11c. Furthermore, a gate of the nMOS 122 is connected to its own drain.

In an aspect, the operation voltage generation unit 12c may also be a diode-connected pMOS. In that case, a drain of the pMOS is connected to the wiring vss and its own gate, and the source is connected to the oscillation circuit 11c and the level shifter 14a.

The oscillation circuit 11c includes the NAND circuit 111 and the plural inverter circuits 112, which is similar to the configuration of the oscillation circuit 11a of the voltage fluctuation detection circuit 10b according to the third embodiment. However, the oscillation circuit 11c is different from the oscillation circuit 11a in that the NAND circuit 111 and the respective inverter circuits 112 are supplied with the grounding potential increased in the operation voltage generation unit 12c via a wiring vssv. For simplicity, in the illustration of FIG. 22, the NAND circuit 111 and a part of the inverter circuits 112 are shown as being connected to the operation voltage generation unit 12c.

The wiring vcc is connected to the NAND circuit 111 and the respective inverter circuits 112. For simplicity, in the illustration of FIG. 22, the NAND circuit 111 and a part of the inverter circuits 112 are shown as being connected to the wiring vcc.

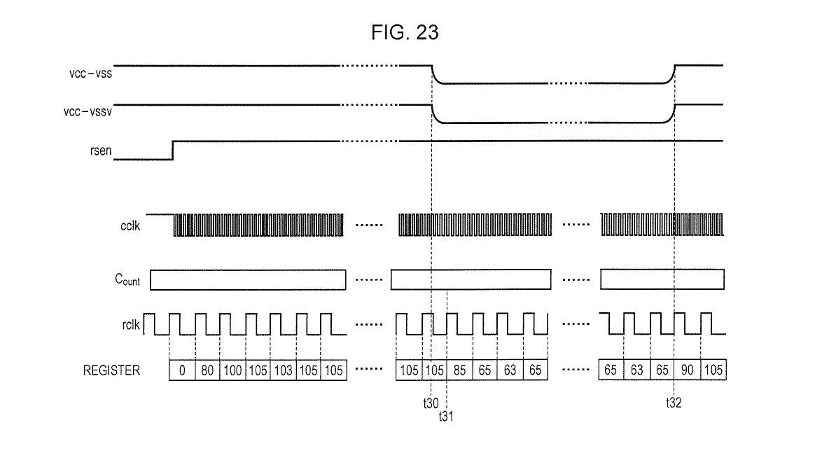

FIG. 23 is a timing chart that illustrates an example operation of the voltage fluctuation detection circuit according to the seventh embodiment.

FIG. 23 illustrates states of the potential difference between the wiring vcc and the wiring vss, the potential difference between the wiring vssv, which connects between the operation voltage generation unit 12c and the oscillation circuit 11c, and the wiring vcc, and the control signal rsen generated in the control signal generation unit 20. Furthermore, the potential of the terminal cclk of the counter 131 (e.g., potential of the output signal of the level shifter 14a), the count value Cₒᵤₙₜ of the counter 131, the potential of the terminal rclk of the counter 131 (e.g., potential of the reference clock), and the value of the register 132 are illustrated. An example of the value of the count C is too detailed, and, as such, is omitted in the example of FIG. 23.

In the example of FIG. 23, between the timings t30 to t32, the potential difference between the wiring vcc and the wiring vss is decreased, for example, because of the influence of the power supply noise and/or the like.

The potential difference between the wiring vssv and the wiring vcc is also decreased, and the oscillation frequency of the oscillation circuit 11c is shortened in response to this change. Accordingly, the count value Cₒᵤₙₜ between the rise of the potential of the terminal rclk and the next rise is low. In the example of FIG. 23, the count value Cₒᵤₙₜ taken in by the register 132, when the potential of the terminal rclk rises at the timing t31, is decreased from “105” to “85”. When the potential difference between the wiring vcc and the wiring vss returns to the original state at the timing t32, the potential difference between the wiring vssv and the wiring vss and the oscillation frequency of the oscillation circuit 11c also return to their respective original states. Accordingly, the count value Cₒᵤₙₜ also returns its value from “65” to “90” and “105”, which were the values at the timing t30 or before.

In this manner, it is possible to detect the fluctuation of the potential difference between the wiring vcc and the wiring vss by detecting the change of the count value Cₒᵤₙₜ as taken in by the register 132.

The effect of the voltage fluctuation detection circuit 10f is similar to that of the voltage fluctuation detection circuit 10b according to the third embodiment illustrated in FIG. 8. That is, since the operation voltage generation unit 12c increases the grounding potential and reduces the potential difference between the wiring vcc and the wiring vss to generate the operation voltage of the oscillation circuit 11c, it is possible to increase the oscillation frequency fluctuation rate λ of the oscillation circuit 11c as compared with the case in which the operation voltage generation unit 12c is not provided. Accordingly, it is possible to improve the sensitivity at which the voltage fluctuation is detected. Further, the above-mentioned consumed energy Eₜₒₜₐₗ can be reduced, so that it is possible to reduce the power consumption.

### Eighth Embodiment

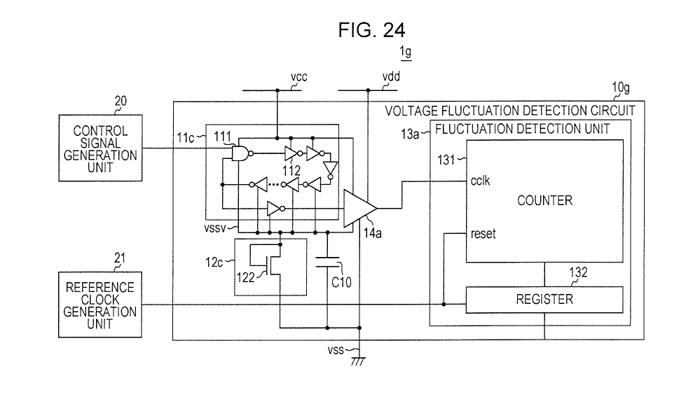

FIG. 24 illustrates examples of a semiconductor integrated circuit and a voltage fluctuation detection circuit according to an eighth embodiment. Elements similar to the elements of the voltage fluctuation detection circuit 10f according to the seventh embodiment illustrated in FIG. 22 are assigned with the same reference symbols.

In a semiconductor integrated circuit 1g according to the eighth embodiment, the capacitative element C10, which is included in the a voltage fluctuation detection circuit 10g, is connected between the wiring vssv, which is arranged between the operation voltage generation unit 12c and the oscillation circuit 11c, and the wiring vss. The capacitative element C10 functions as the coupling capacitance. Similarly as in the voltage fluctuation detection circuit 10d according to the fifth embodiment, and with the provision of the capacitative element C10, it is possible to decrease the PSRR as compared with the case in which the capacitative element C1 is not provided. From the expression (8), since the oscillation frequency fluctuation rate λ can be increased when the PSRR can be decreased, it is possible to improve the sensitivity at which the voltage fluctuation is detected. Further, and as represented in the expression (6), it is possible to reduce the consumed energy Eₜₒₜₐₗ.

Since the operation of the voltage fluctuation detection circuit 10g is similar to the operation of the voltage fluctuation detection circuit 10f according to the seventh embodiment illustrated in FIG. 23, the description thereof will be omitted.

### Ninth Embodiment

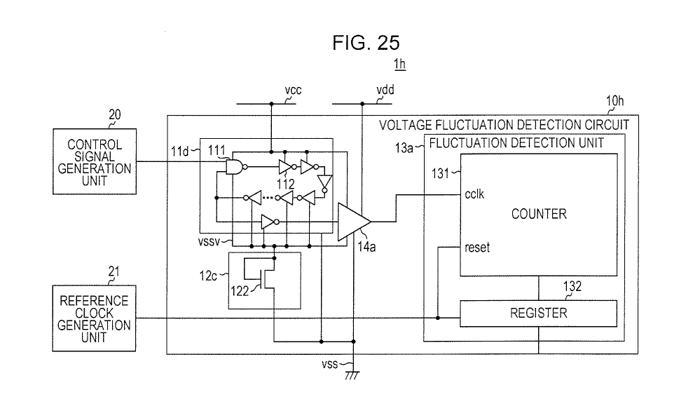

FIG. 25 illustrates examples of a semiconductor integrated circuit and a voltage fluctuation detection circuit according to a ninth embodiment. Elements similar to the elements of the voltage fluctuation detection circuit 10f illustrated in FIG. 22 according to the seventh embodiment are assigned with the same reference symbols.

In a semiconductor integrated circuit 1h and a voltage fluctuation detection circuit 10h according to the ninth embodiment, a p-well of an nMOS included in an oscillation circuit lid is applied with a voltage lower than or equal to the operation voltage. For example, the wiring vss at the grounding potential is electrically connected to the p-well. Although the nMOS is not illustrated in FIG. 25, the nMOS is included in the NAND circuit 111 and the inverter circuits 112.

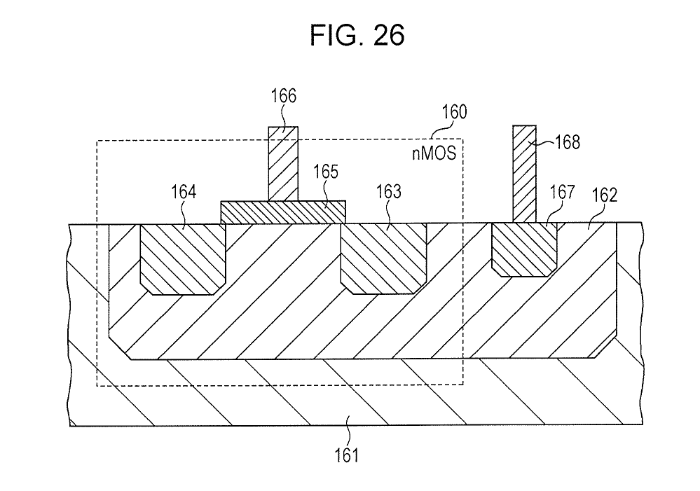

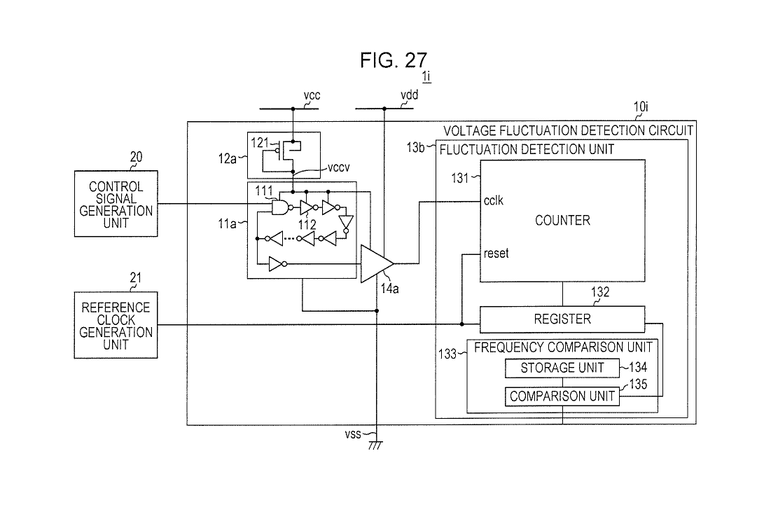

FIG. 26 is a cross sectional view of an example nMOS, which may be included in the oscillation circuit.

An nMOS 160 includes a p-well 162 formed on a substrate 161, n-type source/drain regions 163 and 164, a gate oxide film 165 formed so as to stride over the source/drain regions 163 and 164, and a gate electrode 166 formed on the gate oxide film 165. A high concentration p-type layer 167 for contact is formed in the p-well 162, to which a via 168 is connected. The via 168 is connected to the wiring vss. Accordingly, the p-well 162 is electrically connected to the wiring vss, and the p-well 162 is reversely biased, so that the threshold voltage Vₜₕ of the nMOS 160 is increased.

Since the oscillation frequency fluctuation rate λ can be increased by increasing the threshold voltage Vₜₕ as represented by the expression (7), it is possible to improve the sensitivity for detecting the voltage fluctuation. As represented in the expression (6), the consumed energy Eₜₒₜₐₗ can be decreased, and it is possible to reduce the power consumption.

Since the operation of the voltage fluctuation detection circuit 10h is similar to the operation of the voltage fluctuation detection circuit 10f according to the seventh embodiment, the description thereof will be omitted.

### Tenth Embodiment

FIG. 27 illustrates examples of a semiconductor integrated circuit and a voltage fluctuation detection circuit according to a tenth embodiment. Elements similar to the elements of the voltage fluctuation detection circuit 10b according to the third embodiment are assigned with the same reference symbols.

In a semiconductor integrated circuit 1i and a voltage fluctuation detection circuit 10i according to the tenth embodiment, the fluctuation detection unit 13 includes a frequency comparison unit 133.

The frequency comparison unit 133 is configured to compare the count value output from the register 132, which indicates the magnitude of the oscillation frequency of the oscillation circuit 11a, with a determination reference value and outputs the comparison result. The frequency comparison unit 133 includes a storage unit 134 and a comparison unit 135.

The storage unit 134 is a read only memory (ROM) and/or the like and stores the determination reference value. The comparison unit 135 is configured to compare the count value output from the register 132 with the determination reference value stored in the storage unit 134 and output the comparison result. For example, if the count value is higher than or equal to the determination reference value, the signal at the H level is output. If the count value is lower than the determination reference value, the signal at the L level is output.

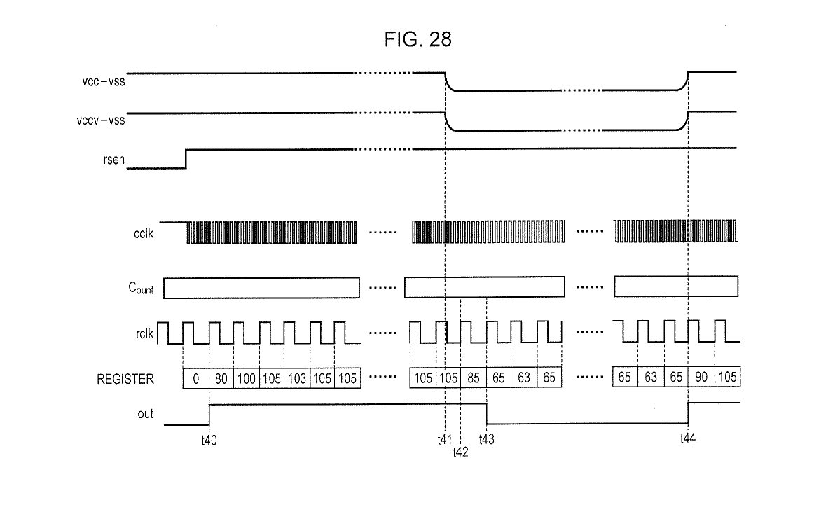

FIG. 28 is a timing chart that illustrates an example operation of the voltage fluctuation detection circuit according to the tenth embodiment.

FIG. 28 illustrates states of the potential difference between the wiring vcc and the wiring vss, the potential difference between the wiring vccv, which connects the operation voltage generation unit 12a and the oscillation circuit 11a, and the wiring vss, and the control signal rsen generated in the control signal generation unit 20. Furthermore, the potential of the terminal cclk of the counter 131 (e.g., potential of the output signal of the level shifter 14a), the count value Cₒᵤₙₜ of the counter 131, the potential of the terminal rclk of the counter 131 (e.g., potential of the reference clock), and the value of the register 132 are illustrated. Furthermore, an output signal “out” of the comparison unit 135 is illustrated. For simplicity, an example of the value of the count C is omitted in the example of FIG. 28.

In the example of FIG. 28, for example, the determination reference value stored in the storage unit 134 is set as 70.

As illustrated in FIG. 28, when the count value taken in by the register 132 is 80 (e.g., at the timing t40), the comparison unit 135 sets the output signal out as the H level since the count value is higher than or equal to the determination reference value at 70.

At the timing t41, the potential difference between the wiring vcc and the wiring vss is decreased due to the influence of, for example, power supply noise. Similarly, and the count value taken in by the register 132 from the timing t42 also starts to decrease under the influence of, for example, the power supply noise. It is noted that since the count value is higher than or equal to the determination reference value at the timing t42, the output signal out remains at the H level. When the count value is below the determination reference value at the timing t43, the comparison unit 135 is configured to set the output signal out as the L level. In the example of FIG. 28, the potential difference between the wiring vcc and the wiring vss returns to the original state at the timing t44, and the count value taken in by the register 132 is 90. At this time, the comparison unit 135 sets the output signal out as the H level since the count value is higher than or equal to the determination reference value.

In this manner, it is possible to detect the fluctuation of the potential difference between the wiring vcc and the wiring vss by detecting the change of the count value taken in by the register 132. In addition, it is possible to detect the fluctuation where the potential difference is large by comparing the determination reference value with the count value and output the comparison result.

The fluctuation detection circuit and the semiconductor integrated circuit according to the various aspects of the present technology have been described above on the basis of the plural embodiments.

In recent years, the demand for low power consumption in semiconductor integrated circuits has become more intense along with the spread of smart phones and sensor devices. In general, the performance and the power (e.g., consumption energy) have an inverse relationship such that performance is decreased to meet the demand for low power consumption.

The fluctuation detection circuits according to the above-mentioned respective embodiments operate the oscillation circuits included therein based on the operation voltage obtained by reducing the detection target voltage. Accordingly, the oscillation frequency fluctuation rate λ of the oscillation circuit is increased, and from the relationship of the expression (6), it is possible to perform the voltage measurement where the consumed energy Eₜₒₜₐₗ is decreased without decreasing the power (e.g., consumption energy). Since the above-mentioned fluctuation detection circuit can be designed by a digital circuit even if a manufacturing technology is changed, the design may be generated in a way that is more desirable than that of a voltage sensor that uses an analog circuit. For this reason, it is conceivable that fluctuation detection circuits configured as described above may be wide-spread.

The fluctuation detection circuit and the semiconductor integrated circuit according to the various aspects of the present technology have been described above, but these are merely examples and are not limited to the above description.

For example, the above-mentioned respective embodiments may be used separately or may be combined. For example, in the voltage fluctuation detection circuit 10a according to the second embodiment, the pMOS 121 and the level shifter 14a of the operation voltage generation unit 12a may be provided in plural poles, and a capacitative element may also be connected between the wiring vdd and the wiring vddv. In another example, in the voltage fluctuation detection circuit 10a according to the second embodiment, the operation voltage generation unit 12a may be connected to the wiring vss instead of to the wiring vdd to increase the grounding potential. In the above-mentioned example, the case has been described in which the frequency comparison unit 133 in the voltage fluctuation detection circuit 10i according to the tenth embodiment is combined with the voltage fluctuation detection circuit 10b according to the third embodiment, but the frequency comparison unit 133 may also be used in the other embodiments.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A voltage fluctuation detection circuit, comprising:
an oscillation circuit configured to receive an operation voltage and perform an oscillation operation;
an operation voltage generation unit configured to reduce a detection target voltage and generate the operation voltage; and
a fluctuation detection unit configured to measure an oscillation frequency of the oscillation circuit and detect a fluctuation of the detection target voltage.

2. The voltage fluctuation detection circuit according to claim 1,
wherein the operation voltage generation unit is further configured to generate the operation voltage that fluctuates in accordance with the fluctuation of the detection target voltage.

3. The voltage fluctuation detection circuit according to claim 1, further comprising:
a level shifter configured to match an amplitude of an output signal of the oscillation circuit with an amplitude of the fluctuation detection unit operation voltage.

4. The voltage fluctuation detection circuit according to claim 1,
wherein the detection target voltage is a potential difference between a first wiring at a first potential and a second wiring at a second potential and the second potential is lower than the first potential, and
wherein the operation voltage generation unit reduces the detection target voltage by reducing the first potential.

5. The voltage fluctuation detection circuit according to claim 4,
wherein an n-well of a p-channel metal-oxide semiconductor field effect transistor (MOSFET) included in the oscillation circuit is applied with a MOSFET voltage higher than or equal to the operation voltage.

6. The voltage fluctuation detection circuit according to claim 1,
wherein the detection target voltage is a potential difference between a first wiring at a first potential and a second wiring at a second potential and the second potential is lower than the first potential, and
wherein the operation voltage generation unit is further configured to reduce the detection target voltage by increasing the second potential.

7. The voltage fluctuation detection circuit according to claim 6,
wherein a p-well of an n-channel MOSFET included in the oscillation circuit is applied with a MOSFET voltage lower than or equal to the operation voltage.

8. The voltage fluctuation detection circuit according to claim 4, further comprising:
a third wiring between the operation voltage generation unit and the oscillation circuit; and
a capacitative element connected to the first wiring or the second wiring.

9. The voltage fluctuation detection circuit according to claim 1,
wherein the operation voltage generation unit is one or a plurality of diode-connected MOSFETs.

10. The voltage fluctuation detection circuit according to claim 1,
wherein the fluctuation detection unit comprises:
a counter configured to count the number of oscillations of the oscillation circuit,
a storage unit configured to hold the number of counts for each predetermined period of time, and
a comparison unit configured to compare the held number of counts with a predetermined determination reference value and output a comparison result.

11. A semiconductor integrated circuit, comprising a voltage fluctuation detection circuit, including:
an oscillation circuit configured to receive an operation voltage and perform an oscillation operation,
an operation voltage generation unit configured to reduce a detection target voltage and generate the operation voltage, and
a fluctuation detection unit configured to measure an oscillation frequency of the oscillation circuit and detect a fluctuation of the detection target voltage.
